(19) United States
(12) Patent Application Publication
(10) Pub. No.: US 2003/0214802 A1
(43) Pub. Date: Nov. 20, 2003

(54) Signal transmission structure with an air dielectric

(76) Inventors: Joseph C. Fjelstad, Maple Valley, WA (US); Belgacem Haba, Cupertino, CA (US); Para K. Segaram, Campbell, CA (US)

Correspondence Address: Shemwell Gregory & Courtney LLP, Suite 201, 4880 Stevens Creek Boulevard, San Jose, CA, 95129, US

(21) Appl. No.: 10/418,762

(22) Filed: Apr. 18, 2003

Related U.S. Application Data
(63) Continuation-in-part of application No. 10/094,761, filed on Mar. 11, 2002.
(60) Provisional application No. 60/298,679, filed on Jun. 15, 2001.
(60) Provisional application No. 60/347,776, filed on Jan. 11, 2002.
(60) Provisional application No. 60/382,290, filed on May 22, 2002.
(60) Provisional application No. 60/442,040, filed on Jan. 23, 2003.

(51) Int. Cl. H05K 3/36; H05K 3/02; H05K 9/00; H02B 1/20

(52) U.S. Cl. 361/826; 29/847; 29/868; 29/830; 361/816

(57) ABSTRACT

The dielectric constant and loss tangent of a signal transmission structure is lowered by locating discrete conductors used for signal transmission between two shields so as to form cavities between the discrete conductors and each of the shields. Each cavity is filled with any of a number and/or combination of dielectric supports and/or dielectric materials, including air. The discrete conductors are formed across the cavities so that any exposed surfaces of the discrete conductors are in contact with the dielectric material of the respective cavity.

### RELATED APPLICATIONS

This application claims priority from and is a continuation-in-part application of U.S. patent application Ser. No. 10/094,761, entitled TRANSMISSION STRUCTURE WITH AN AIR DIELECTRIC, filed Mar. 11, 2002, which is currently pending, and which claims priority from U.S. Provisional Application No. 60/298,679, entitled ULTRA LOW LOSS, LOW DIELECTRIC CONSTANT CONDUCTOR CONSTRUCTIONS FOR CARRYING ELECTRICAL/ELECTRONIC SIGNALS AND METHODS FOR THEIR MANUFACTURE, filed Jun. 15, 2001, and U.S. Provisional Application No. 60/347,776, entitled HIGH PERFORMANCE SIGNAL LAYERS FOR BACKPLANE AND RELATED CONSTRUCTIONS AND METHODS FOR THEIR MANUFACTURE, filed Jan. 11, 2002.

This application also claims priority from U.S. Patent Application No. 60/373,168, entitled HIGH SPEED LOW LOSS PCB MODULE, filed Apr. 17, 2002, U.S. Patent Application No. 60/382,290, entitled HIGH SPEED SIGNAL TRANSMISSION STRUCTURES, filed May 22, 2002, and U.S. Patent Application No. 60/442,040, entitled IMPROVED TRANSMISSION LINE STRUCTURES WITH AN AIR DIELECTRIC AND METHOD FOR MANUFACTURE, filed Jan. 23, 2003.

### TECHNICAL FIELD

The disclosed embodiments relate generally to a transmission structure and, more particularly, to a transmission structure with an air dielectric.

### BACKGROUND

In early circuit designs, loss of signal strength was not of great concern because signal transmission speeds were relatively slow and were transmitted directly through copper or other metal conductors. Consequently, the dielectric constant and loss tangent of the substrate and associated coating materials were not critical.

The dielectric constant (permittivity) (Dₖ) is the amount of electrical energy stored per unit volume in an insulator when an electrical field is imposed across the insulator. The dielectric constant is expressed in terms of a ratio of the permittivity in the insulator to the permittivity in a vacuum. A lower dielectric constant Dₖ supports faster conductor signal speed as well as thinner interconnects for the same conductor geometries.

The dielectric loss tangent, also referred to as the dielectric dissipation factor (D_{f}), is the degree of dielectric loss, and is expressed as a ratio of the real portion of the complex dielectric constant to the imaginary portion of a complex dielectric constant. A lower dielectric loss tangent allows for improved signal integrity with high frequencies and less signal loss at high frequencies.

In more recent circuit designs, however, signal transmission speeds have increased significantly making the loss of signal strength during transmission a critical issue. For example, at higher frequencies, the dielectric constant and loss tangent of a substrate and the associated coating materials used in combination with the conductors become more critical. The higher frequency signals propagate along the surface of the metal conductor, and are therefore impeded and degraded by the electrical properties (i.e., dielectric constant and loss tangent) of the dielectric materials that are adjacent to the conductor. There are also concerns about the parasitic loss of signal due to a build-up of capacitance in the substrate.

As a result of the issues associated with the degradation of signal strength during high-speed signal transmission, many attempts have been made to provide electronic materials and structures capable of supporting high-speed signal transmission both in substrates and in interconnection cables while minimizing the signal distortion. One way to mitigate these issues was to use and/or create materials having ever better dielectric/electrical properties such as lower dielectric constants and loss tangents.

Among the best dielectric materials for use in signaling applications are materials found in the family of fluoropolymers such as E. I. Du Pont's TEFLON® (also known as polytetrafluoroethylene (PTFE)). These fluoropolymers have dielectric constants in the range of 2.0-2.8. Other dielectric materials such as polypropylene have dielectric constants lower than the fluoropolymers, however, they have other properties such as strength and temperature limitations that make them less desirable for electronics manufacture. Table 1 includes some of the dielectric materials that have been used alone or in combination in the manufacturing of electronic components used in signal transmission applications.

TABLE 1

| Dielectric | Dielectric |
|---|---|
| Material | Constant |
| Air | 1 |
| Polypropylene | 1.5 |
| Polytetra fluoroethylene | 2.0 |
| TEFLON ®, PTFE | 2.0 |
| TEFLON ®, FEP | 2.1 |
| Polyethylene | 2.2-2.4 |
| TEFLON ®, PCTFE | 2.3-2.8 |
| Rubber (isomerized) | 2.4-3.7 |
| Styrene (modified) | 2.4-3.8 |
| Bisbenzocyclobutene (BCB) | 2.5 |
| Polyamide | 2.5-2.6 |
| Polyimide | 2.8 |
| Polyester resin | 2.8-4.5 |
| Polycarbonate | 2.9-3.0 |
| Silicone rubber | 3.2-9.8 |
| Epoxy resin (cast) | 3.6 |
| Polyester resin (glass fiber filled) | 4.0-4.5 |
| Polyester resin (flexible) | 4.1-5.2 |
| Silicon dioxide | 4.5 |
| Phenol resin | 4.9 |
| Alumina | 9.3-11.5 |
| Silicon | 11.0-12.0 |

The information of Table 1 shows, however, the lowest dielectric constant to be that of air, which has a dielectric constant of 1.0. Thus, in an attempt to lower the dielectric constant and hence increase the performance of materials typically used in components of signaling applications, air began to be included in combination with other dielectric materials through processes by which the air was combined or foamed with the other dielectric materials.

A variety of methods have been used to foam insulating materials with air. These are described, for example, in U.S. Pat. Nos. 4,680,423 and 5,110,998. Although this foaming process helps to lower the effective dielectric constant of the materials so produced, the surfaces of the resulting dielectric materials remain largely intact, meaning that the loss of signal strength at the surface of the material is not greatly improved.

An early approach to taking advantage of the dielectric properties of air involved spirally wrapping a conductor wire with one or more strands of polymer, effectively holding them uniformly away from a circumferential ground reference. Alternatively, U.S. Pat. No. 4,939,317 described a round conductor wrapped in perforated polyimide tape to lower the effective dielectric constant of the material without resorting to more exotic materials. These wrapping techniques proved most suitable for round wire and cable constructions such as coaxial cables. While contact between the polymer strands and the conductor was greatly minimized, thereby reducing skin effect loss, the number of conductors that could be effectively handled was minimal.

In yet another attempt to lower the effective dielectric constant of materials, U.S. Pat. Nos. 3,953,566 and 4,730,088 disclosed the use of polytetrafluroethylene (PTFE) as a dielectric. However, the PTFE material was expensive and difficult to process in comparison to more commonly used dielectric materials. The PTFE-based dielectrics remain attractive for their performance capability but also have limits in high performance applications.

To improve on the performance of PTFE components, U.S. Pat. No. 4,740,088 described drilling holes into PTFE dielectric materials using heat rays, particle rays or laser drilling. In addition, U.S. Pat. Nos. 4,443,657 and 4,701,576 described the use of sintering. Further, porous expanded PTFE materials were described in U.S. Pat. Nos. 3,953,566, 3,962,153, 4,096,227, 4,187,390, and 4,902,423. In each case, however, the suggested methods only added processing costs to the expense of the PTFE material.

Still other attempts were made to create materials that provide still lower dielectric constants and loss tangents. U.S. Pat. No. 5,286,924, for example, described a cable construction utilizing an insulator consisting of a cellular construction of porous polypropylene. As manufactured, the porous dielectric has an air equivalent volume in excess of 70% and a dielectric constant of less than 1.2. Likewise, U.S. Pat. No. 5,744,756 describes a high-speed signal transmission cable with spaced, parallel conductors having an insulation layer comprised of a blown microfiber web surrounding the conductors to lower the dielectric constant of the material. Although these dielectric materials exhibited excellent electrical properties when used as cable dielectrics, the process used in their manufacture was complex which made them expensive to produce. Consequently, efforts to provide materials and structures that support high-speed signal transmission while minimizing signal loss have continued.

### BRIEF DESCRIPTION OF THE DRAWINGS

FIG. 1A shows the separated layers of an air dielectric transmission structure, under an embodiment.

FIG. 1B shows an exploded view of the air dielectric transmission structure, under the embodiment of FIG. 1A.

FIG. 1C shows a cut-away plan view of the air dielectric transmission structure, under the embodiment of FIG. 1A.

FIG. 1D shows a cross-sectional view of the air dielectric transmission structure, under the embodiment of FIG. 1A.

FIG. 1E shows a cross-sectional view of the air dielectric transmission structure, under an alternative embodiment of FIG. 1A.

FIG. 2A is a cross-sectional view of an air dielectric transmission structure, under other alternative embodiments of FIG. 1A.

FIG. 2B is a cross-sectional view of an air dielectric transmission structure, under other alternative embodiments of FIG. 1A.

FIG. 2C is a cross-sectional view of an air dielectric transmission structure including multiple layers of conductors, under other alternative embodiments of FIG. 1A.

FIG. 2D is a cross-sectional view of an air dielectric transmission structure, under an alternative embodiment of FIG. 1A.

FIG. 3A shows an air dielectric transmission structure, under yet other alternative embodiments of FIG. 1A.

FIG. 3B shows an air dielectric transmission structure, under an alternative embodiment of FIG. 3A.

FIG. 4 shows an air dielectric transmission structure, under yet other alternative embodiments of FIG. 1A.

FIG. 5 shows an air dielectric transmission structure, under yet other alternative embodiments of FIG. 1A.

FIG. 6A shows an air dielectric transmission structure, under yet other alternative embodiments of FIG. 1A.

FIG. 6B shows an air dielectric transmission structure, under an alternative embodiment of FIG. 6A.

FIG. 7 shows an air dielectric transmission structure, under yet other alternative embodiments of FIG. 1A.

FIG. 8 shows an air dielectric transmission structure, under an alternative embodiment of FIG. 3A.

FIG. 9 shows an air dielectric transmission structure, under another alternative embodiment of FIG. 3A.

FIG. 10 shows an air dielectric transmission structure, under yet another alternative embodiment of FIG. 3A.

FIG. 11 shows an air dielectric transmission structure, under yet another alternative embodiment of FIG. 1A.

FIG. 12 shows an air dielectric transmission structure, under an alternative embodiment of FIG. 11.

FIG. 13 shows an air dielectric transmission structure, under an alternative embodiment of FIG. 12.

FIG. 14A is an air dielectric transmission structure in which air is the dielectric medium between broad side coupled conductors, under an embodiment.

FIG. 14B is an air dielectric transmission structure in which air is the dielectric medium between broad side coupled conductors, under an alternative embodiment of FIG. 14A.

FIGS. 15A-15I show a method of forming an air dielectric transmission structure, under an embodiment.

FIG. 16 shows a method for forming a printed circuit module that includes an air dielectric transmission structure on the surface layers of the module interconnection substrates, under an embodiment.

FIG. 17 shows a method for forming a printed circuit module that includes an air dielectric transmission structure on the surface layers of the module interconnection substrates, under an alternative embodiment.

FIG. 18 shows a method for forming a printed circuit module that includes an air dielectric transmission structure on the surface layers of the module interconnection substrates, under another alternative embodiment.

FIG. 19 is a memory module or card that includes an air dielectric transmission structure on the surface layers of the module interconnection substrates, under any of the embodiments of FIGS. 16, 17 and 18.

FIG. 20 is a side view of a memory module structure that includes an air dielectric transmission structure and a thermal spreader, under any of the embodiments of FIGS. 16, 17 and 18.

FIGS. 21A-21C show various views of a backplane including an air dielectric transmission structure, under an embodiment.

FIGS. 21D and 21E show views of a backplane including an air dielectric transmission structure with solid insulating material, under an alternative embodiment.

FIG. 22 is a plan view illustrating a curved section of an air dielectric transmission system, under an embodiment.

FIG. 23 is a plan view illustrating a printed circuit board including an air dielectric transmission system, under an embodiment.

FIGS. 24A and 24B are cross-sectional views of a connector mating with an air dielectric transmission system, under an embodiment.

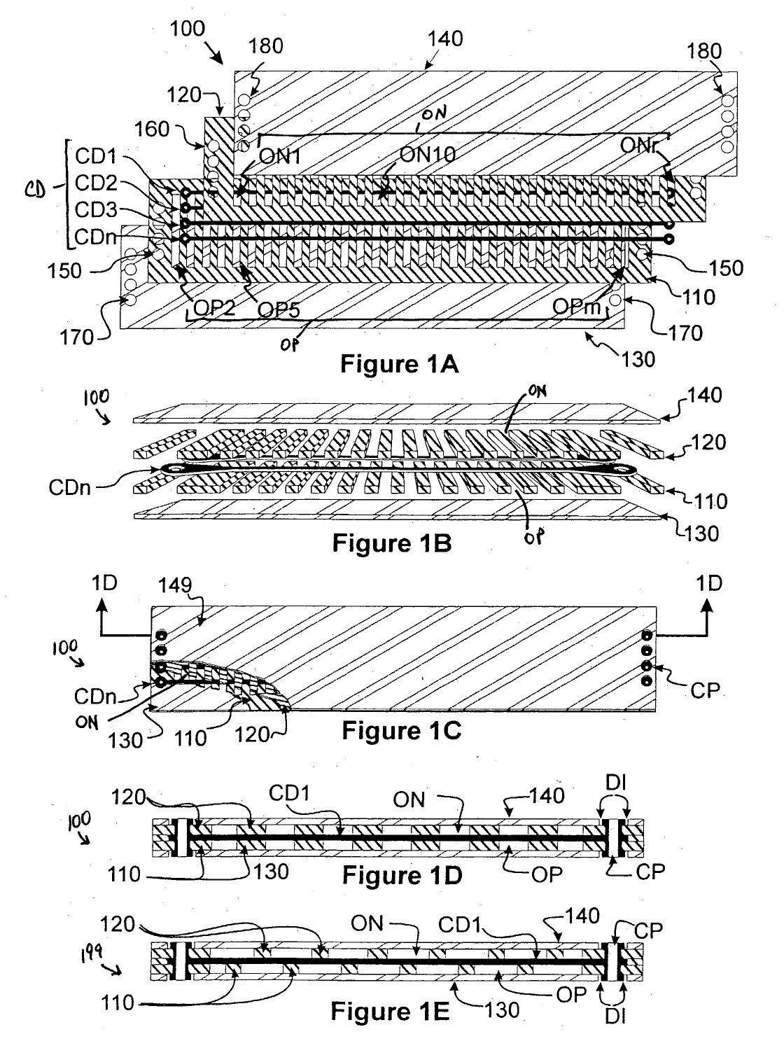

In the drawings, the same reference numbers identify identical or substantially similar elements or acts. To easily identify the discussion of any particular element or act, the most significant digit or digits in a reference number refer to the Figure number in which that element is first introduced (e.g., element 130 is first introduced and discussed with respect to FIG. 1). Any modifications necessary to the Figures can be readily made by one skilled in the relevant art based on the detailed description provided herein.

### DETAILED DESCRIPTION

Air dielectric transmission structures having reduced dielectric constants and loss tangents, and methods for forming the air dielectric transmission structures, are described below. The air dielectric transmission structures are suitable for use in high-speed electronic signal transmission interconnection structures, but are not so limited. In the following description, for purposes of explanation, specific nomenclature is set forth and specific details are introduced to provide a thorough understanding of, and enabling description for, embodiments of the present invention. One skilled in the relevant art, however, will recognize that the present invention can be practiced without one or more of these specific details, or with other components, systems, etc. In other instances, well-known circuits, devices, structures or operations are not shown, or are not described in detail, to avoid obscuring aspects of the invention.

FIGS. 1A-1E show numerous views of an air dielectric transmission structure 100, under an embodiment. FIG. 1A shows the separated layers 110-140 of the dielectric transmission structure 100, under an embodiment. FIG. 1B is an exploded view of the air dielectric transmission structure 100, under the embodiment of FIG. 1A. FIG. 1C is a cut-away plan view of the air dielectric transmission structure 100, under the embodiment of FIG. 1A. FIG. 1D is a cross-sectional view of the air dielectric transmission structure 100 along the line ID-ID (FIG. 1C), under the embodiment of FIG. 1A. FIG. 1E is a cross-sectional view of the air dielectric transmission structure 199 along the line 1D-1D (FIG. 1C), under an alternative embodiment of FIG. 1A.

With reference to FIGS. 1A-1E, air dielectric transmission structure 100 includes a dielectric support 110 that has one or more spaced-apart openings OP, also referred to herein as a series of openings OP1-OPm. The dielectric support 110 includes at least one dielectric material in at least one of a solid form and a porous form, but is not so limited as any combination and/or form of dielectric material known in the art can be used. At least one conductor CD, also referred to herein as a series of conductors CD1-CDn, contacts and/or couples to dielectric support 110. The series of conductors CD includes one or more conductors placed in any number of arrangements known in the art. For example, the conductors CD of an embodiment are arranged in parallel (when more than one conductor is present), but the embodiment is not so limited. The conductors CD contact dielectric support 110 such that each conductor CD is formed over some portion of an opening OP.

The size of an opening OP, including the length and width of the opening OP, is a function of the number of conductors CD included in the air dielectric transmission structure 100, also referred to as the transmission structure 100. As an example, the length of an opening OP increases with the number of conductors CD, but is not so limited. Further to the example, the width of the opening OP is as wide as possible, considering the geometry and structural support limits of the particular transmission structure 100, including the need to maintain the structural integrity of the conductors CD without gravity induced deformation or sag, and the tensile strength and other design considerations of the transmission structure 100. Alternatively, a variety of length and width combinations are possible for the openings OP.

Regarding numbers of openings OP, various alternative embodiments can include dielectric supports that have any number of openings OP. Consequently, the number of openings OP is varied according to application, for example, and relative positions of and spacing among the openings OP can be periodic or aperiodic, but are not so limited under the embodiments herein.

The air dielectric transmission structure 100 also includes another dielectric support 120 that has one or more spaced-apart openings ON, also referred to herein as a series of openings ON1-ONr. As with dielectric support 110, the additional dielectric support 120 also contacts conductors CD such that each conductor CD is configured over each opening ON. As a result, the conductors CD are sandwiched or fixed between the two dielectric supports 110 and 120. To reduce capacitive losses, the size of the conductors CD can be narrowed at points where the conductors CD cross over or contact the dielectric supports 110 and 120.

The dielectric supports 110 and 120 of an embodiment are nearly the same in terms of size and configuration, but are not so limited. The dielectric supports 110 and 120 contact the conductors CD such that the openings OP and ON are substantially in register with each other. For example, openings OP and ON are vertically aligned with each other in the transmission structure 100 of an embodiment. Further, openings OP and ON are vertically offset from each other in the transmission structure 199 (FIG. 1E) of one alternative embodiment; the amount of vertical offset is not limited under the description herein.

In addition to the two dielectric supports 110 and 120, the transmission structure 100 includes a first shield 130 that is coupled to dielectric support 110, and a second shield 140 that is coupled to dielectric support 120. The first and second shields 130 and 140 can directly contact the respective dielectric supports 110 and 120, while alternative embodiments can include other materials and/or components between the shields 130 and 140 and the dielectric supports 110 and 120. The shields 130 and 140, while being spaced apart from conductors CD by the respective dielectric supports 110 and 120, provide a reference ground.

Referring to FIG. 1A, external couplings to the conductors CD are made by including contact openings 150 and 160 in the dielectric supports 110 and 120, respectively. The contact openings 150 and 160 of an embodiment are vertically aligned with each other when contacting the conductors CD, regardless of the alignment of openings OP and ON, but are not so limited. Further, the shields 130 and 140 also include contact openings 170 and 180 which have vertical centerlines that are vertically aligned with the vertical centerlines of contact openings 150 and 160, respectively.

Related to the contact openings 150-180, and with reference to FIGS. 1C, 1D, and 1E, the transmission structures 100 and 199 include a number of connector plugs CP that are formed in contact with the contact openings 150, 160, 170, and 180. The connector plugs of an embodiment are plated through holes, but are not so limited. The connector plugs CP form an electrical coupling with the conductors CD, and are spaced apart from shields 130 and 140 via dielectric openings DI. The dielectric openings DI serve to prevent the connector plugs CP, and therefore the conductors CD, from shorting to ground. The dielectric openings DI are filled with a dielectric material, but can be filled with any of a variety of non-conducting materials in alternative embodiments.

The air dielectric transmission structure 100 can additionally include a plastic jacket (not shown) that is formed around one or both of the shields 130 and 140. The plastic jacket protects one or both of the shields 130 and 140 from corrosive environments or other adverse environmental effects and/or physical damage, but is not so limited. Furthermore, other materials can be added to the transmission structure 100 between the shields 130 and 140 and the plastic jacket to provide the transmission structure 100 with a particular cross-sectional shape and/or size, as desired.

The components of the air dielectric transmission structure 100 described above can be modified, reconfigured, and/or repositioned in numerous ways to form a variety of alternative embodiments. Following are select examples of alternative embodiments of the transmission structure 100. While the following alternatives are presented for illustrative purposes, various equivalent modifications are possible as is application of the teachings herein to transmission structures other than the transmission structures described above.

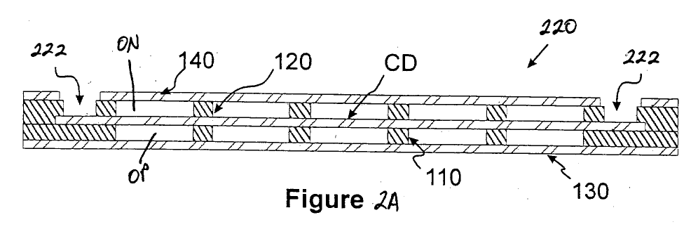

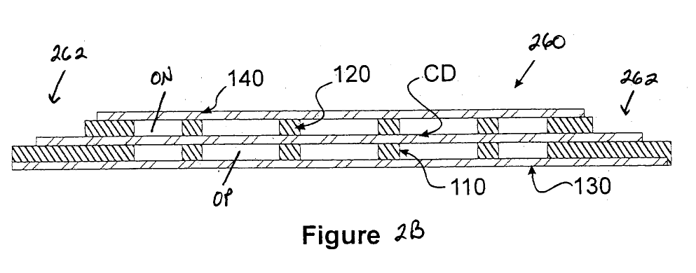

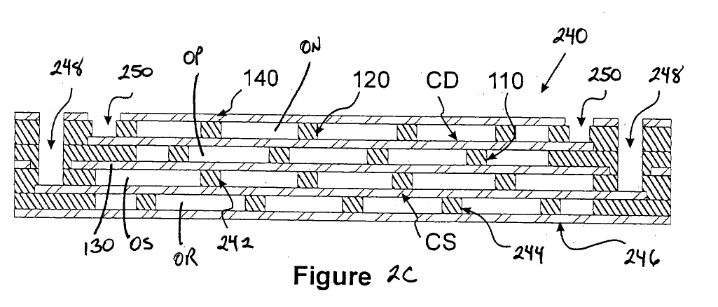

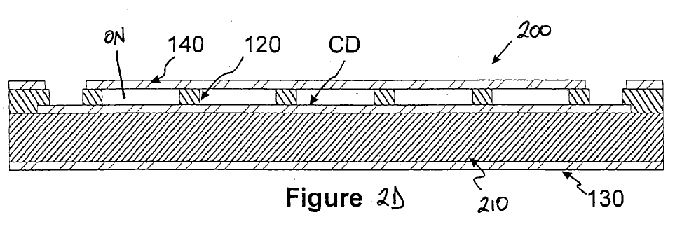

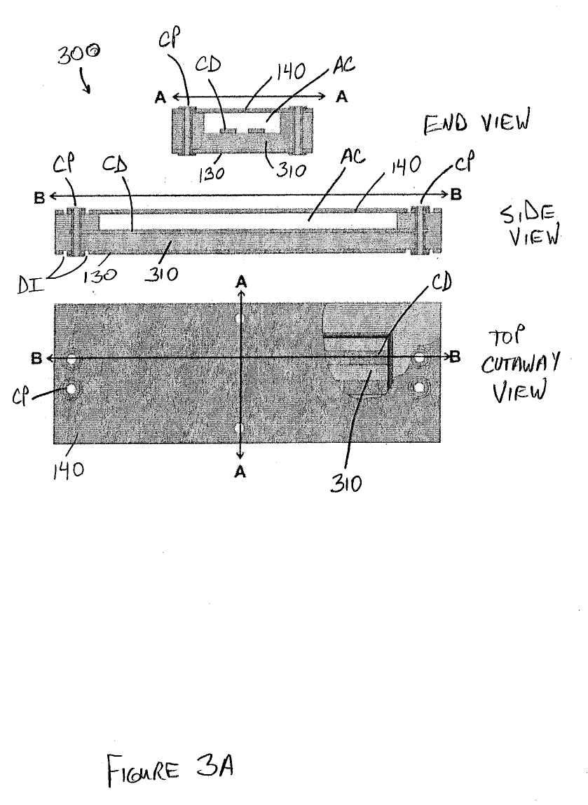

FIGS. 2A-2D show cross-sectional views of numerous air dielectric transmission structures, under alternative embodiments of FIGS. 1A-1E. FIG. 2A is a cross-sectional view of an air dielectric transmission structure 220, under other alternative embodiments of FIG. 1A. The transmission structure 220 includes connector openings 222 formed through dielectric layer 120 to expose the conductors CD. As shown, the width of the opening through shield 140 can be wider than the width of the opening through dielectric layer 120, but the size of the opening is not so limited.

FIG. 2B is a cross-sectional view of an air dielectric transmission structure 260, under other alternative embodiments of FIG. 1A. The transmission structure 260 includes access to the different layers of the transmission structure 260 using stair-step ends 262, where the access is used for couplings to structures of the transmissions structure 260 and the like. The stair-step ends 262 are formed by removing a portion of the end section of the first shield 140. Further, a slightly smaller portion of the end section of the first dielectric support 120 is also removed, thereby exposing a section of the underlying conductors CD. In addition, an even smaller portion of the end section of the conductors CD can also be removed. The size of the removed portions from each of the first shield 140, first dielectric support 120, and the conductors CD (if removed) are determined according to particular applications in which the transmission structure 260 is used and particular devices coupling to the transmission structure 260.

FIG. 2C is a cross-sectional view of an air dielectric transmission structure 240 including multiple layers of conductors, under other alternative embodiments of FIG. 1A. While the transmission structure 240 has two layers of conductors, alternative embodiments can have any number of layers of conductors. The transmission structure 240 includes a dielectric support 110 that has one or more spaced-apart openings OP. A series of conductors CD contact dielectric support 110, where the series of conductors CD includes one or more conductors in any number of configurations. The conductors CD contact dielectric support 110 such that each conductor CD is formed over some portion of an opening OP. The transmission structure 240 also includes another dielectric support 120 that has one or more spaced-apart openings ON. This additional dielectric support 120 also contacts conductors CD such that each conductor CD is configured over each opening ON. The transmission structure 240 includes, as described above, a first shield 130 that is coupled to dielectric support 110, and a second shield 140 that is coupled to dielectric support 120.

The transmission structure 240 further includes a third dielectric support 242 that couples to the first shield 130. The third dielectric support 242 includes one or more spaced-apart openings OS. A series of conductors CS contact the third dielectric support 242, where the series of conductors CS includes one or more conductors in any number of configurations. The conductors CS contact the third dielectric support 242 such that each conductor CS is formed over some portion of an opening OS.

The transmission structure 240 also includes a fourth dielectric support 244 that has one or more spaced-apart openings OR. The fourth dielectric support 244 also contacts conductors CS such that each conductor CS is configured over each opening OR. The transmission structure 240 includes a third shield 246 that is coupled to the fourth dielectric support 244, but is not so limited. The third and fourth dielectric structures 242 and 244 are similar in size and configuration to dielectric structures 110 and 120, but can have a different size and/or configuration. Likewise, the conductors CS are similar in size, configuration, and number to the conductors CD, but alternative embodiments are not so limited.

The multi-layer transmission structure 240 of an embodiment includes a first set of connector openings 248 that provide access for couplings to the conductors CS. The first set of connector openings 248 is formed through dielectric structures 110, 120, and 242, but alternative embodiments can form connector openings through the third shield 246 and the fourth dielectric structure 244. The transmission structure 240 also includes a second set of connector openings 250 that provide access for couplings to the conductors CD. The widths of the first and second set of connector openings 248 and 250 through the first shield 140 can be wider than the width of the opening through the underlying dielectric structure, but are not so limited.

FIG. 2D is a cross-sectional view of an air dielectric transmission structure 200, under an alternative embodiment of FIG. 1A. The transmission structure 200 includes a dielectric support 120 that has a series of openings ON. A series of conductors CD contact dielectric support 120. The series of conductors CD includes one or more conductors placed in any number of arrangements known in the art. The conductors CD contact dielectric support 120 such that each conductor CD is formed over some portion of an opening OP.

The transmission structure 200 also includes another dielectric support 210 that is a solid dielectric layer 210. As with dielectric support 120, the solid dielectric support 210 also contacts the conductors CD so that the conductors CD are sandwiched or fixed between the two dielectric supports 120 and 210. Thus, transmission structure 200 uses air as a dielectric on only one side of the conductors CD.

In addition to the two dielectric supports 120 and 210, the transmission structure 200 includes a first shield 130 that is coupled to the solid dielectric support 210, and a second shield 140 that is coupled to the first dielectric support 120. The first and second shields 130 and 140 can directly contact the respective dielectric supports 210 and 120, while alternative embodiments can include other materials and/or components between the shields 130 and 140 and the dielectric supports 210 and 120. The shields 130 and 140, while being spaced apart from the conductors CD by the respective dielectric supports 210 and 120, provide a reference ground. The transmission structure 200 with an air dielectric on one side of the conductor is used in applications that transfer signals having mid-range frequencies, but is not so limited.

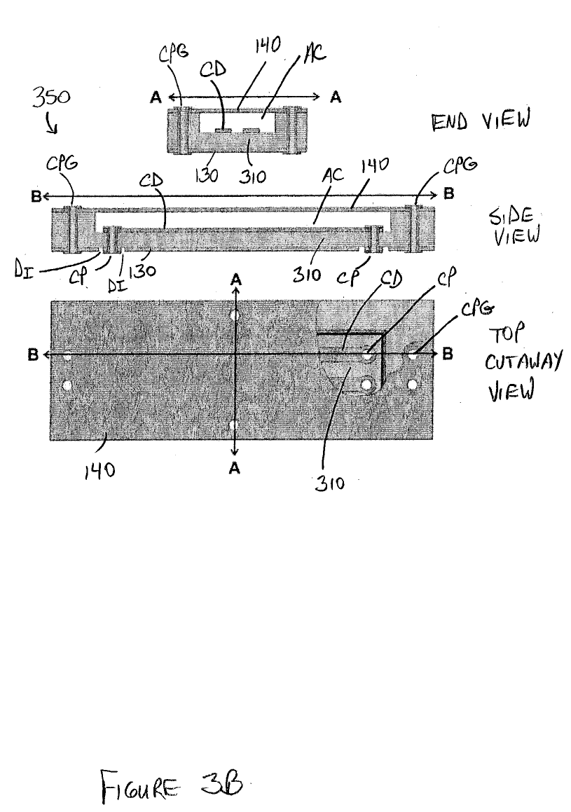

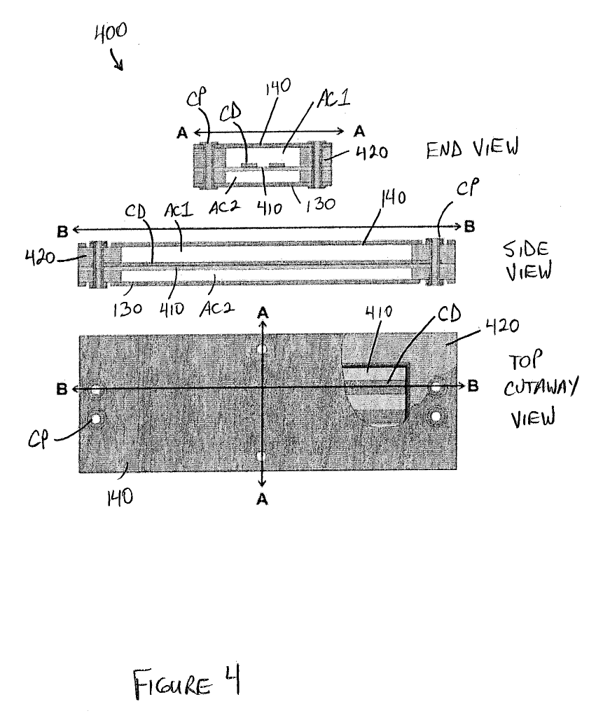

FIG. 3A shows an air dielectric transmission structure 300, under yet other alternative embodiments of FIG. 1A. The transmission structure 300 includes at least one solid dielectric support or layer 310. A series of conductors CD contact a side of the dielectric support 310. The series of conductors CD includes one or more conductors placed in any number of arrangements known in the art.

In addition to the solid dielectric support 310, the transmission structure 300 includes a first shield 130 that is coupled to the solid dielectric support 310. The transmission structure 300 also includes a second shield 140 that is coupled to the transmission structure 300 on an opposite side of the solid dielectric support 310 from the first shield 130. The second shield 140 is coupled to the transmission structure 300 so as to form an air cavity AC above the conductors CD. The shields 130 and 140, while being spaced apart from the conductors CD by the respective solid dielectric support 310 and the air cavity AC, provide a reference ground.

The transmission structure 300 also includes connector plugs CP that are plated through holes, but are not so limited. The connector plugs CP form an electrical coupling with the conductors CD, and are spaced apart from shields 130 and 140 via dielectric openings DI. The dielectric openings DI serve to prevent the connector plugs CP, and therefore the conductors CD, from shorting to ground. The dielectric openings DI are filled with a dielectric material, but can be filled with any of a variety of non-conducting materials in alternative embodiments.

FIG. 3B shows an air dielectric transmission structure 350, under an alternative embodiment of FIG. 3A. The transmission structure 350 includes at least one solid dielectric support or layer 310. A series of conductors CD contact a side of the dielectric support 310. The series of conductors CD includes one or more conductors placed in any number of arrangements known in the art.

In addition to the solid dielectric support 310, the transmission structure 350 includes a first shield 130 that is coupled to the solid dielectric support 310. The transmission structure 350 also includes a second shield 140 that is coupled to the transmission structure 350 on an opposite side of the solid dielectric support 310 from the first shield 130. The second shield 140 is coupled to the transmission structure 350 so as to form an air cavity AC above the conductors CD. The shields 130 and 140, while being spaced apart from the conductors CD by the respective solid dielectric support 310 and the air cavity AC, provide a reference ground.

The transmission structure 350 also includes two sets of connector plugs CP and CPG that are plated through holes, but are not so limited. The first set of connector plugs CP form an electrical coupling with the conductors CD, and are spaced apart from shield 130 via dielectric openings DI. The dielectric openings DI serve to prevent the connector plugs CP, and therefore the conductors CD, from shorting to ground. The dielectric openings DI are filled with a dielectric material, but can be filled with any of a variety of non-conducting materials in alternative embodiments. The second set of connector plugs CPG forms an electrical coupling between the shields (grounds) 130 and 140.

FIG. 4 shows an air dielectric transmission structure 400, under yet other alternative embodiments of FIG. 1A. The transmission structure 400 includes at least one solid dielectric support or layer 410 coupled to a support frame or structure 420. A series of conductors CD contact a side of the dielectric support 410. The series of conductors CD includes one or more conductors placed in any number of arrangements known in the art.

In addition to the solid dielectric support 410, the transmission structure 400 includes a first shield 130 that is coupled to a first side of the support frame 420. The first shield 130 is coupled to the support frame 420 so as to form a first air cavity AC1 above the conductors CD. The transmission structure 400 also includes a second shield 140 that is coupled to a second side of the support frame 420, where the first and the second sides of the support frame 420 are opposite on another, but the embodiment is not so limited. The second shield 140 is coupled to the support frame 420 so as to form a second air cavity AC2 below the dielectric support 410. The shields 130 and 140 provide a reference ground, but are not so limited.

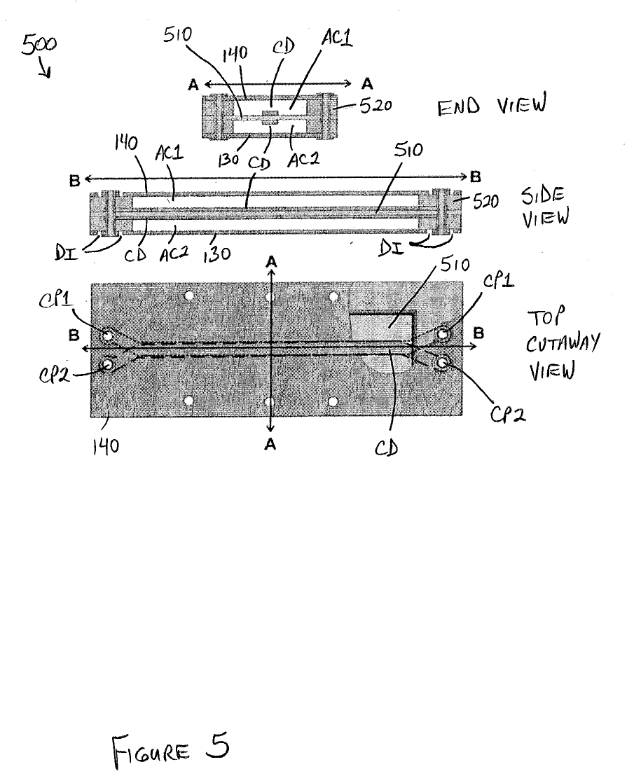

FIG. 5 shows an air dielectric transmission structure 500, under yet other alternative embodiments of FIG. 1A. The transmission structure 500 includes at least one solid dielectric support or layer 510 coupled to a support frame or structure 520. A series of conductors CD are broadside coupled and contact both the top and bottom sides of the dielectric support 510, but the embodiment is not so limited. The series of conductors CD includes one or more conductors placed in any number of arrangements known in the art. As an example, the conductors CD can be placed on the dielectric support 510 according to the polarity of their respective signals, where the conductors CD on one side of the dielectric support 510 carry positive polarity signals while the conductors CD on the opposite side of the dielectric support 510 carry negative polarity signals, but the embodiment is not so limited.

In addition to the solid dielectric support 510, the transmission structure 500 includes a first shield 130 that is coupled to a first side of the support frame 520. The first shield 130 is coupled to the support frame 520 so as to form a first air cavity AC1 above the conductors CD on a first side of the dielectric support 510. The transmission structure 500 also includes a second shield 140 that is coupled to a second side of the support frame 520, where the first and the second sides of the support frame 420 are opposite on another, but the embodiment is not so limited. The second shield 140 is coupled to the support frame 520 so as to form a second air cavity AC2 below the conductors CD on a second side of the dielectric support 510. The shields 130 and 140 provide a reference ground, but are not so limited.

The transmission structure 500 also includes two sets of connector plugs CP1 and CP2 that are plated through holes, but are not so limited. The first set of connector plugs CP1 form an electrical coupling with the conductors CD on the first side of the dielectric support 510. The second set of connector plugs CP2 form an electrical coupling with the conductors CD on the second side of the dielectric support 510. The connector plugs CP1 and CP2 are spaced apart from the shields 130 and 140 via dielectric openings DI. The dielectric openings DI serve to prevent the connector plugs CP, and therefore the conductors CD, from shorting to ground. The dielectric openings DI are filled with a dielectric material, but can be filled with any of a variety of non-conducting materials in alternative embodiments.

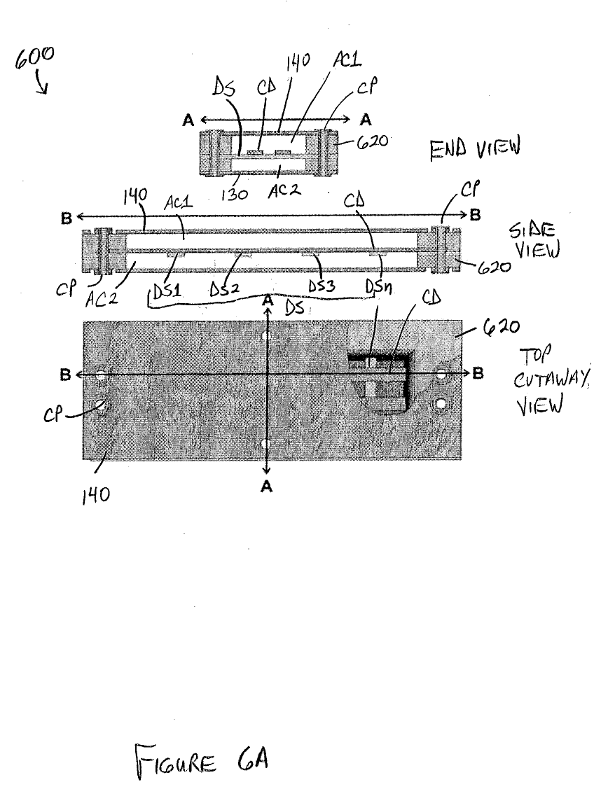

FIG. 6A shows an air dielectric transmission structure 600, under yet other alternative embodiments of FIG. 1A. The transmission structure 600 includes a discontinuous dielectric support DS coupled to a support frame or structure 620. The discontinuous dielectric support DS minimizes contact between the conductors CD and the dielectric support DS.

The dielectric support DS includes one or more dielectric members DS, also referred to herein as a series of dielectric members DS1-DSn. The size and shape of the dielectric members DS varies according to the numbers of dielectric members DS used in the transmission structure 600. The dielectric members DS are placed relative to each other and/or relative to the support frame 620 using a spacing SP, where SP can be uniform or non-uniform, but is not so limited. The dielectric members DS arc arranged in a parallel configuration (when more than one support is used), but the embodiment is not so limited.

A series of conductors CD contacts and/or couples to at least one side of the dielectric support DS. The series of conductors CD includes one or more conductors placed in any number of arrangements known in the art. For example, the conductors CD of an embodiment are placed in an orthogonal configuration relative to the dielectric members DS, and a parallel configuration (when more than one conductor CD is used) relative to other conductors CD, but the embodiment is not so limited. The conductors CD contact each dielectric member DS such that each conductor CD is formed over some portion of each dielectric member DS.

In addition to the dielectric supports DS, the transmission structure 600 includes a first shield 130 that is coupled to a first side of the support frame 620. The first shield 130 is coupled to the support frame 620 so as to form a first air cavity AC1 above the conductors CD. The transmission structure 600 also includes a second shield 140 that is coupled to a second side of the support frame 620, where the first and the second sides of the support frame 620 are opposite on another, but the embodiment is not so limited. The second shield 140 is coupled to the support frame 620 so as to form a second air cavity AC2 below the dielectric supports DS. The shields 130 and 140 provide a reference ground, but are not so limited.

FIG. 6B shows an air dielectric transmission structure 650, under an alternative embodiment of FIG. 6A. The transmission structure 650 includes a discontinuous dielectric support DS coupled to a support frame or structure, where the dielectric support DS includes a series of dielectric members DS. A series of conductors CD contacts and/or couples to at least one side of the dielectric supports DS. The series of conductors CD includes one or more conductors placed in an orthogonal configuration relative to the dielectric members DS, as described above. The conductors CD contact each dielectric member DS such that each conductor CD is formed over some portion of each dielectric member DS.

The transmission structure 650 includes first and second ground shields 660 and 670 instead of the shields 130 and 140, which are typically metal foil, found in transmission structure 600 (FIG. 6A). Each ground shield 660 and 670 includes a metal-clad composite structure including a composite or insulating core 672 having at least one metal-clad outer surface 674. These ground shields provide additional strength to the transmission structure 650, thereby preventing sagging of the ground shields. Further, the metal-clad outer surface 674 can be used as a substrate for conductor traces, but is not so limited.

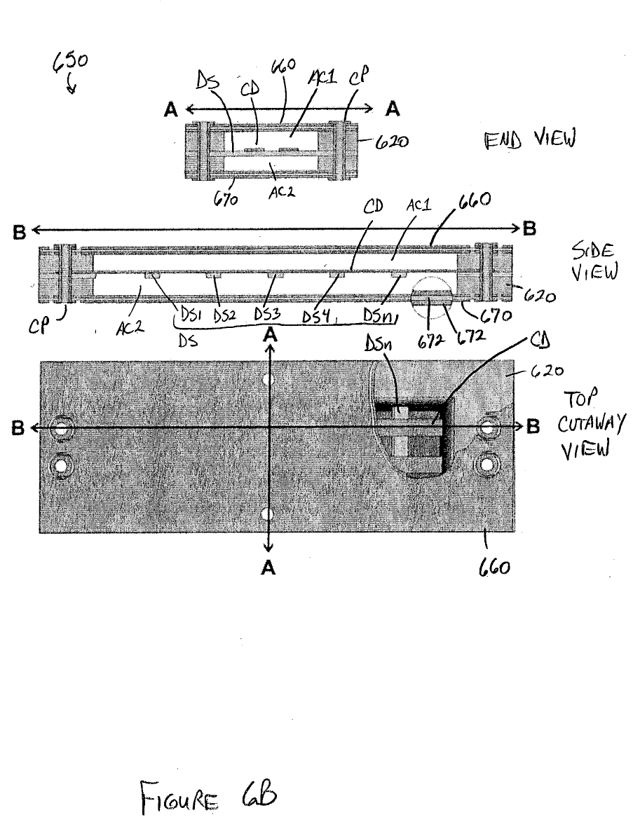

FIG. 7 shows an air dielectric transmission structure 700, under yet other alternative embodiments of FIG. 1A. The transmission structure 700 includes a hybrid structure 702 in which a series of conductors CD or conducting regions are integral to the dielectric material 710 or dielectric support. The series of conductors CD includes one or more conductors placed in any number of arrangements known in the art. The hybrid structure 702 is coupled to a support frame or structure 720.

In addition to the hybrid structure 702, the transmission structure 700 includes a first shield 130 that is coupled to a first side of the support frame 720. The first shield 130 is coupled to the support frame 720 so as to form a first air cavity AC1 above the conductors CD. The transmission structure 700 also includes a second shield 140 that is coupled to a second side of the support frame 720, where the first and the second sides of the support frame 720 are opposite on another, but the embodiment is not so limited. The second shield 140 is coupled to the support frame 720 so as to form a second air cavity AC2 below the dielectric support 710. The hybrid structure 702 allows near-full exposure to air in the first and second air cavities AC1 and AC2 by both sides of the conductors CD. The shields 130 and 140 provide a reference ground, but are not so limited.

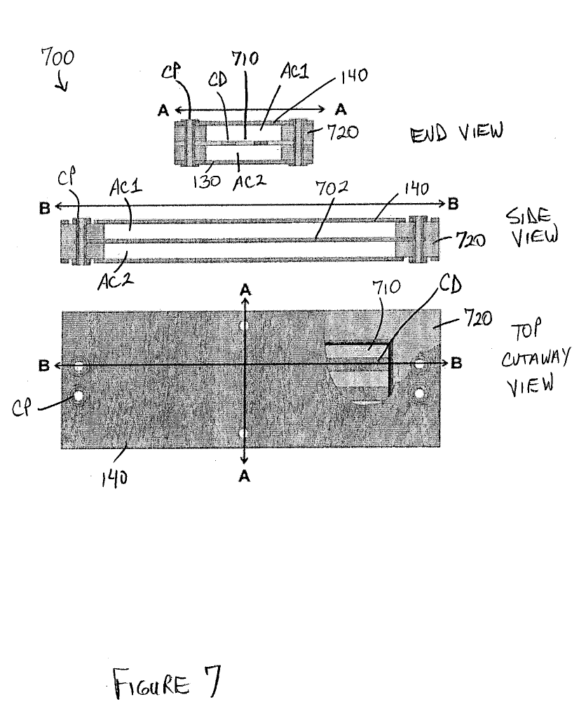

FIG. 8 shows an air dielectric transmission structure 800, under an alternative embodiment of FIG. 3A. The transmission structure 800 includes at least one solid dielectric support or layer 810. A series of conductors CD contact a side of the dielectric support 810. The series of conductors CD includes one or more conductors placed in any number of arrangements known in the art.

The solid dielectric support 810 is undercut using etching, in an embodiment, to remove some portion of material of the dielectric support 810 that is under the conductors CD. Removal of the dielectric material under the dielectric support 810 reduces the capacitance and the dielectric losses associated with signal propagation across the conductors CD. Various alternative embodiments of the dielectric support 810 can have differing amounts of material etched away from the dielectric support.

In addition to the solid dielectric support 810, the transmission structure 800 includes a first shield 130 that is coupled to the solid dielectric support 810. The transmission structure 800 also includes a second shield 140 that is coupled to the transmission structure 800 on an opposite side of the solid dielectric support 810 from the first shield 130. The second shield 140 is coupled to the transmission structure 800 so as to form an air cavity AC above the conductors CD. The shields 130 and 140, while being spaced apart from the conductors CD by the respective solid dielectric support 810 and the air cavity AC, provide a reference ground.

The transmission structure 800 also includes two sets of connector plugs CP and CPG that are plated through holes, but are not so limited. The first set of connector plugs CP form an electrical coupling with the conductors CD, and are spaced apart from shield 130 via dielectric openings DI. The dielectric openings DI serve to prevent the connector plugs CP, and therefore the conductors CD, from shorting to ground. The dielectric openings DI are filled with a dielectric material, but can be filled with any of a variety of non-conducting materials in alternative embodiments. The second set of connector plugs CPG forms an electrical coupling between the shields (grounds) 130 and 140.

FIG. 9 shows an air dielectric transmission structure 900, under another alternative embodiment of FIG. 3A. The transmission structure 900 includes at least one solid dielectric support or layer 910. A series of conductors CD contact a side of the dielectric support 910. The series of conductors CD includes one or more conductors placed in any number of arrangements known in the art. The dielectric support 910 also includes additional layers of material 930 and 940 internal to the dielectric support 910. The internal layers of material 930 and 940 can form, for example, additional support structure and/or additional circuitry or conductive signal paths, but are not so limited. While two layers of internal material 930 and 940 are shown in the dielectric support 910, any number of internal layers is present in alternative embodiments.

The transmission structure 900 also includes a first shield 130 that is coupled to the solid dielectric support 910, and a second shield 140 that is coupled to an opposite side of the solid dielectric support 910 from the first shield 130. The second shield 140 is coupled to the transmission structure 900 so as to form an air cavity AC above the conductors CD.

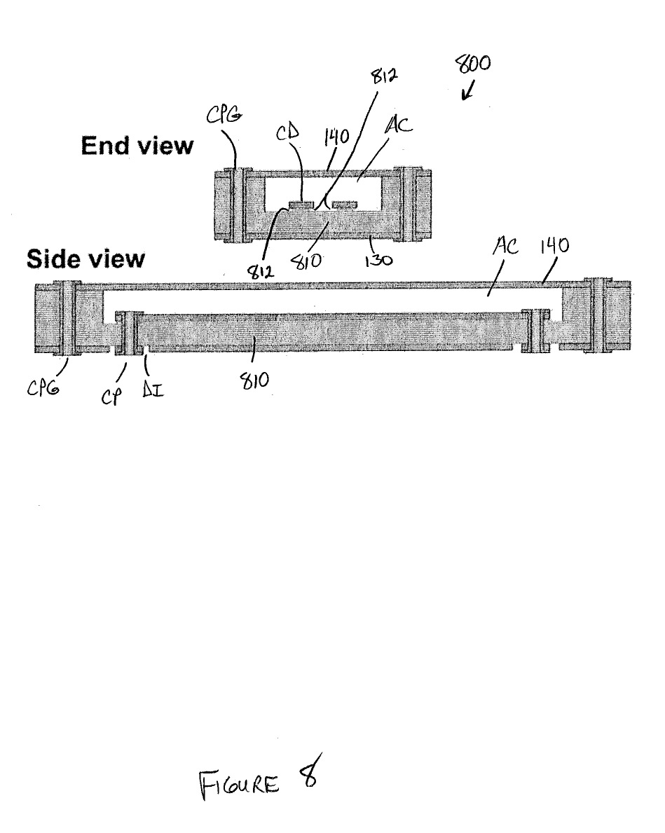

FIG. 10 shows an air dielectric transmission structure 1000, under yet another alternative embodiment of FIG. 3A. The transmission structure 1000 includes at least one solid dielectric support or layer 1010. A series of conductors CD contact a side of the dielectric support 1010, where the series of conductors CD includes one or more conductors placed in any number of arrangements known in the art. The transmission structure 1000 also includes a first shield 130 that is coupled to the solid dielectric support 1010, and a second shield 140 that is coupled to an opposite side of the solid dielectric support 1010 from the first shield 130. The second shield 140 is coupled to the transmission structure 1000 so as to form an air cavity AC above the conductors CD.

The dielectric support 1010 also includes additional layers of insulating material 1030 and 1040. The insulating material 1030 and 1040 is applied to any internal conductor surface, for example, to modify the dielectric performance of the associated surface and/or to protect the surface, but is not so limited. While insulating material 1030 and 1040 is shown on an internal surface of the second shield 140, the dielectric support 1010, and the conductors CD, insulating material is applied to any number and/or combinations of internal surfaces in alternative embodiments.

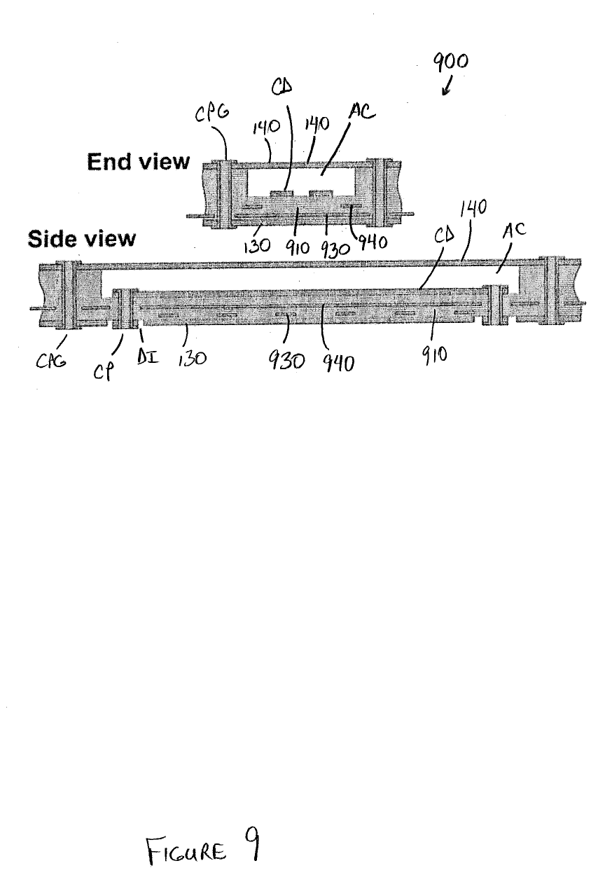

FIG. 11 shows an air dielectric transmission structure 1100, under yet another alternative embodiment of FIG. 1A. The transmission structure 1100 includes a support frame or structure 1120. A first shield 130 is coupled to a first side of the support frame 1120, and a second shield 140 is coupled to a second side of the support frame 1120, where the first and the second sides of the support frame 1120 are opposite on another, but the embodiment is not so limited. The shields 130 and 140 provide a reference ground, but are not so limited.

The first and second shields 130 and 140 along with the support frame 1120 form a cavity 1130 within the transmission structure 1100. The cavity 1130 of an embodiment is filled with a particulate dielectric material 1140, and the particulate dielectric material 1140 supports a series of conductors CD that includes one or more conductors CD placed in any number of arrangements known in the art. While the conductors CD of an embodiment are place approximately equidistant from the first and second shields 130 and 140, the conductors CD can be placed at any of a number of positions between the first and second shields 130 and 140.

The particulate dielectric material 1140, while supporting the conductors CD, provides a relatively low dielectric constant when compared to a solid dielectric material as a result of the discontinuous nature of the particulate insulating material. Likewise, the size and properties of the particles of the particulate dielectric material 1140 affect the associated dielectric constant. A ceramic powder used as the particulate dielectric material 1140, for example, results in a low loss tangent but a higher average dielectric constant. Many types and/or combinations of types of particulate dielectric material 1140 are contemplated under the transmission structure 1100.

FIG. 12 shows an air dielectric transmission structure 1200, under an alternative embodiment of FIG. 11. The transmission structure 1200 includes a support frame or structure 1220. A first shield 130 is coupled to a first side of the support frame 1220, and a second shield 140 is coupled to a second side of the support frame 1220, where the first and the second sides of the support frame 1220 are opposite on another, but the embodiment is not so limited. The shields 130 and 140 provide a reference ground, but are not so limited.

The first and second shields 130 and 140 along with the support frame 1220 form a first cavity 1230 within the transmission structure 1200. The first cavity 1230 of an embodiment is filled with a dielectric material 1232 having a configuration that supports the conductors CD and minimizes the contact area with the conductors CD. For example, the dielectric material of an embodiment is in a sawtooth configuration, where a side of the dielectric material 1232 has portions removed to form a material in which regions of the material have, for example, triangular, pyramidal, and/or wedge shapes. The tips of the wedges of the dielectric material 1232 support a first side of a series of conductors CD that includes one or more conductors CD placed in any number of arrangements known in the art. While the conductors CD of an embodiment are place approximately equidistant from the first and second shields 130 and 140, the conductors CD can be placed at any of a number of positions between the first and second shields 130 and 140.

The first and second shields 130 and 140 along with the support frame 1220 also form a second cavity 1240 within the transmission structure 1200. Like the first cavity 1230, the second cavity 1240 of an embodiment is filled with a dielectric material 1242 having a sawtooth configuration. The tips of the wedges of the dielectric material 1242 support a second side of the conductors CD. The triangular shapes formed in the dielectric materials 1232 and 1242 serve to minimize the contact surface of the dielectric materials 1232 and 1242 with the conductors.

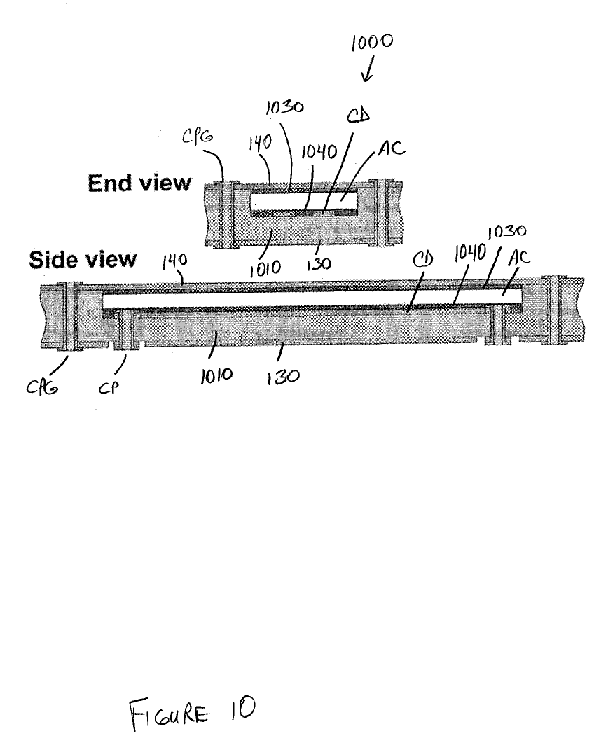

FIG. 13 shows an air dielectric transmission structure 1300, under an alternative embodiment of FIG. 12. The transmission structure 1300 includes a support frame or structure 1320, a first shield 130 coupled to a first side of the support frame 1320, and a second shield 140 coupled to a second side of the support frame 1320. The shields 130 and 140 provide a reference ground, but are not so limited.

The first and second shields 130 and 140 along with the support frame 1320 form a first cavity 1330 within the transmission structure 1300. The first cavity 1330 of an embodiment is filled with a dielectric material 1332 having a configuration that supports the conductors CD and minimizes the contact area with the conductors CD. For example, the dielectric material of this embodiment has a cylindrical shape. A portion of the edge of the dielectric material 1332 makes tangential contact with and supports a first side of a series of conductors CD that includes one or more conductors CD placed in any number of arrangements known in the art. The cylindrical dielectric material 1332 is configured orthogonally to the conductors CD, but numerous configurations of the dielectric material 1332 are contemplated hereunder. While the conductors CD of an embodiment are place approximately equidistant from the first and second shields 130 and 140, the conductors CD can be placed at any of a number of positions between the first and second shields 130 and 140.

The first and second shields 130 and 140 along with the support frame 1320 also form a second cavity 1340 within the transmission structure 1300. Like the first cavity 1330, the second cavity 1340 of an embodiment is filled with a cylindrical dielectric material 1342. A portion of the edges of the cylindrical dielectric material 1342 support a second side of the conductors CD.

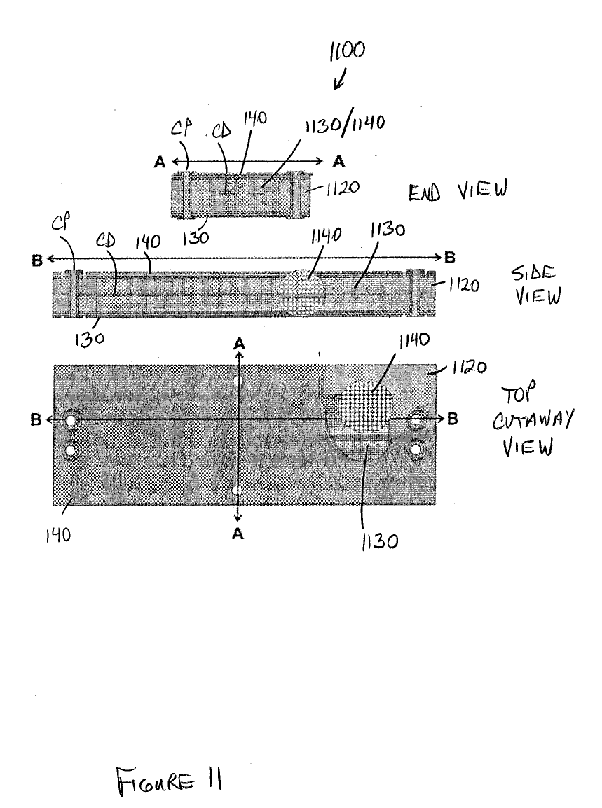

FIG. 14A is an air dielectric transmission structure 1400 in which air is the dielectric medium between broad side coupled conductors, under an embodiment. The transmission structure 1400 includes a first conductive shield 1410 coupled to a first layer of polymer film 1412, also referred to as a first polymer structure 1412. The polymer film 1412 can be perforated to reduce the dielectric constant, as described above with reference to the openings of the dielectric support. A first set of conductors CD1 is supported on the first polymer structure 1412, where the first set of conductors CD1 includes one or more conductors or conductive traces placed in any number of arrangements known in the art.

The transmission structure 1400 further includes a second conductive shield 1420 coupled to a second layer of polymer film 1422, also referred to as a second polymer structure 1422. A second set of conductors CD2 is supported on the second polymer structure 1422, where the second set of conductors CD2 includes one or more conductors or conductive traces placed in any number of arrangements known in the art.

In forming the transmission structure 1400, the first and second conductive shields 1410 and 1420 are configured so that the respective sets of corresponding conductors CD1 and CD2 are facing each other. The conductors CD1 and CD2 are aligned so that they are substantially in register with each other. For example, conductors CD1 and CD2 are vertically aligned with each other in the transmission structure 1400 of an embodiment. Further, conductors CD1 and CD2 can be vertically offset from each other by some amount in the transmission structure of alternative embodiments, where the amount of vertical offset is not limited under the description herein.

A series of dielectric supports 1430 is fixed or sandwiched between the opposing conductive shields 1410 and 1420, where the dielectric supports 1430 define a precise standoff gap or distance in the transmission structure 1400 between the opposing conductors CD1 and CD2 of the respective conductive shields 1410 and 1420. The series of dielectric supports 1430 includes one or more dielectric structures in the form of multifilament fibers or strands aligned with and occupying at least a portion of at least one of the gaps or openings between the conductors CD1 and CD2. To reduce capacitive losses, the multifilament fibers of the dielectric supports 1430 are sized to minimize contact with the conductors CD, but are not so limited.

The dielectric supports can carry an epoxy or resin to provide an integral bonding material to the transmission structure 1400, but are not so limited. The dielectric supports of alternative embodiments can be formed from any number and/or combination of dielectric materials having any number and/or combination of different shapes. Further, the dielectric supports of alternative embodiments can occupy any number and/or pattern of gaps between the conductors CD1 and CD2, limited only by the structural considerations (e.g., sag, tensile strength, etc.) of the transmission structure 1400. Moreover, the dielectric supports of alternative embodiments can occupy any portion and/or region of any combination of gaps between the conductors CD1 and CD2, limited only by the structural considerations (e.g., sag, tensile strength, etc.) of the transmission structure 1400.

FIG. 14B is an air dielectric transmission structure 1450 in which air is the dielectric medium between broad side coupled conductors, under an alternative embodiment of FIG. 14A. The transmission structure 1450 includes a first conductive shield-1410 coupled to a first polymer structure 1412. A first set of conductors CD1 is supported on the first polymer structure 1412. The transmission structure 1450 also includes a second conductive shield 1420 coupled to a second polymer structure 1422. A second set of conductors CD2 is supported on the second polymer structure 1422.

The first and second conductive shields 1410 and 1420 are configured so that the respective sets of corresponding conductors CD1 and CD2 are facing each other. A series of supports 1530 is fixed or sandwiched between the opposing conductive shields 1410 and 1420, where the supports 1530 define a precise standoff gap or distance in the transmission structure 1450 between the opposing conductors CD1 and CD2 of the respective conductive shields 1410 and 1420.

The series of supports 1530 includes one or more conductors 1532 encased in a dielectric insulation 1534. The supports 1530 of an embodiment are round, but are not so limited. The series of supports 1530 are aligned with and occupy at least a portion of at least one of the gaps or openings between the conductors CD1 and CD2. To reduce capacitive losses, the supports 1530 are sized to minimize contact with the conductors CD, but are not so limited. The conductors 1532 are used to provide a return electrical path and/or shielding within an associated cable structure, but are not so limited.

The supports of alternative embodiments can be formed from any number and/or combination of materials having any number and/or combination of different shapes. Further, the supports of alternative embodiments can occupy any number and/or pattern of gaps between the conductors CD1 and CD2, limited only by the structural considerations (e.g., sag, tensile strength, etc.) of the transmission structure 1450. Moreover, the supports of alternative embodiments can occupy any portion and/or region of any combination of gaps between the conductors CD1 and CD2, limited only by the structural considerations (e.g., sag, tensile strength, etc.) of the transmission structure 1450.

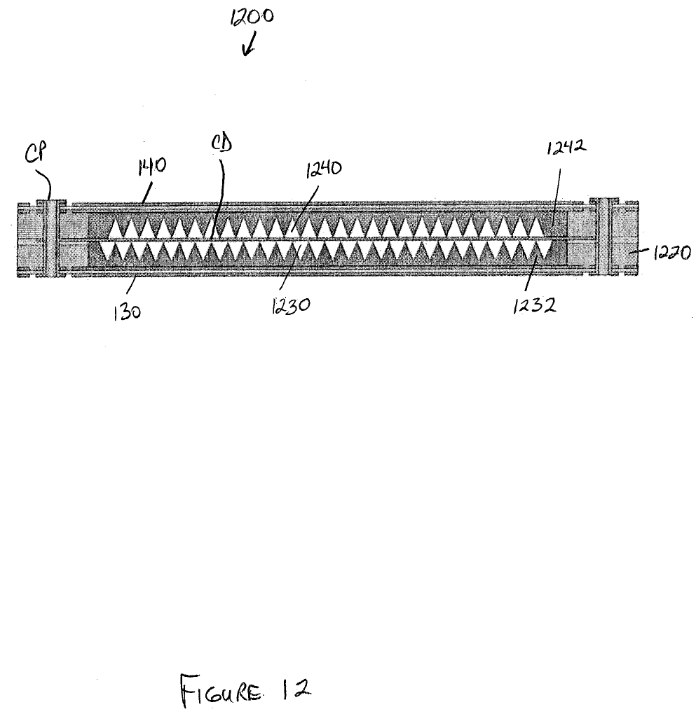

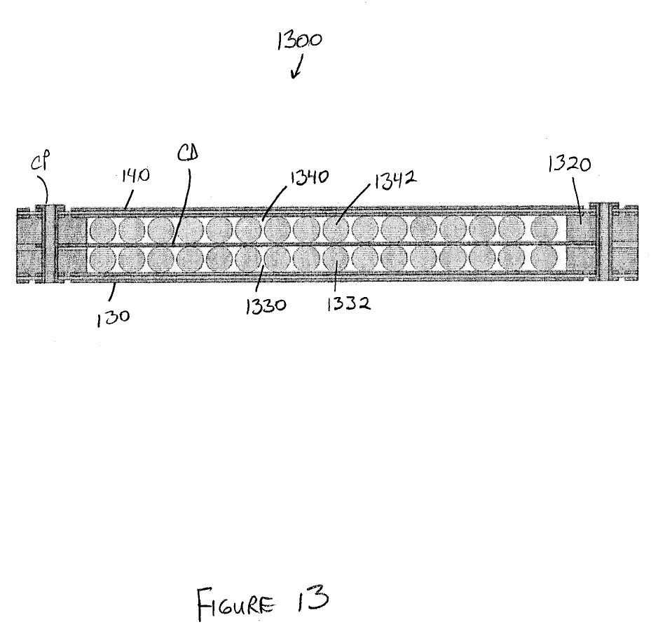

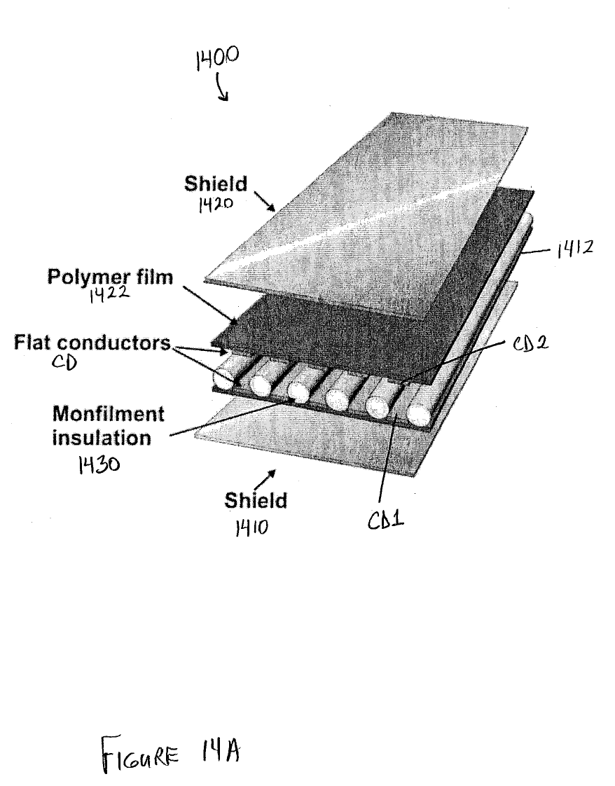

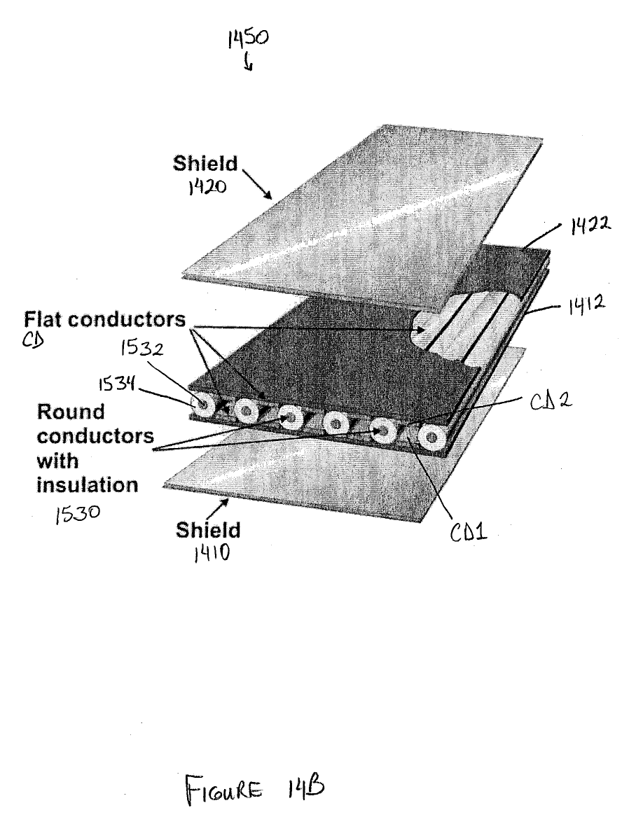

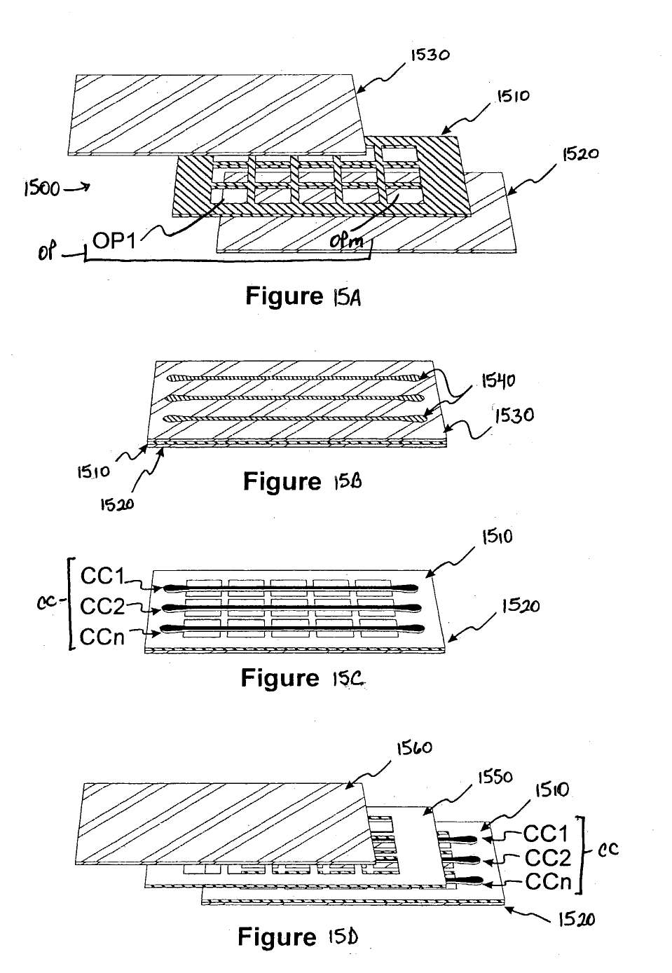

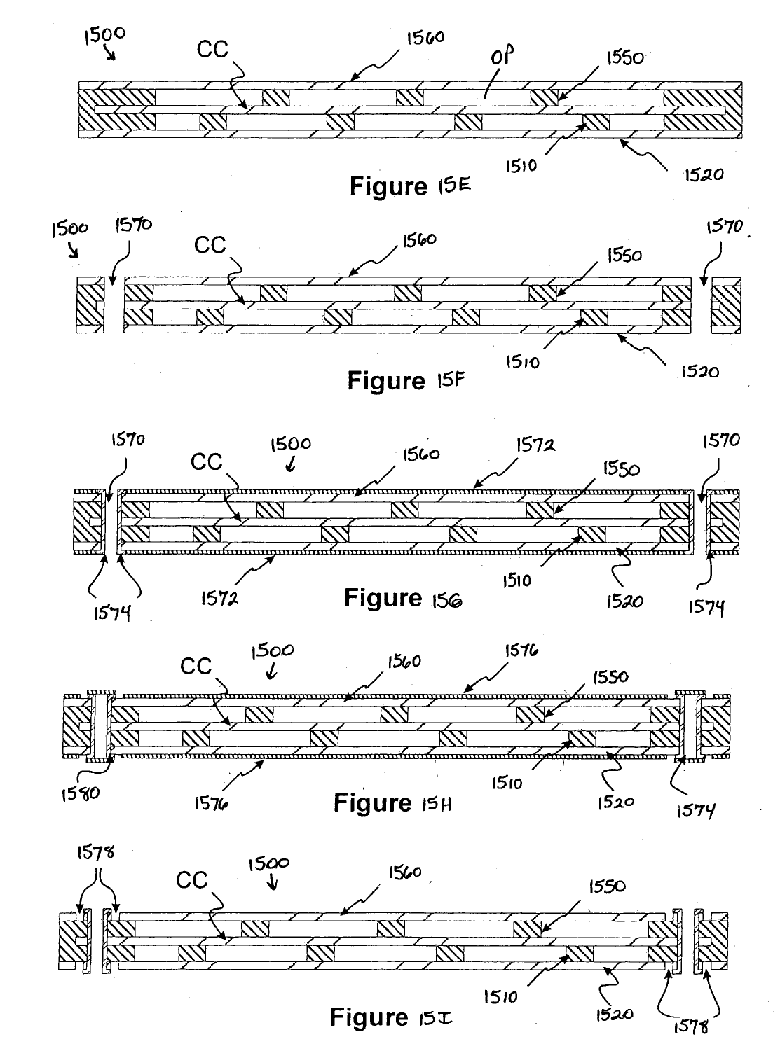

FIGS. 15A-15I show a method for forming an air dielectric transmission structure 1500, under an embodiment. Referring to FIG. 15A, the method of formation includes the use of first and second dielectric supports 1510 and 1550, first and second conductive shields 1520 and 1560, and a layer of conductive material 1530, as described above.

The first dielectric support 1510 is formed using conventional processes and materials. For example, a polymer film in a roll or sheet can be perforated to form openings OP. While materials with a low dielectric constant are preferred electrically for use in forming the first dielectric support 1510, the influence of the physical properties of the first dielectric support 1510 on the transmission structure 1500 is relatively small. Consequently, materials with higher dielectric constants can also be used to form the first dielectric support 1510.

The first dielectric support 1510 includes a series of spaced-apart openings OP1-OPm, collectively referred to herein as openings OP. The length of the openings OP formed in the first dielectric support 1510 is a function of the number of conductors to be formed across the first dielectric support 1510, where the length of the openings OP increases as the number of conductors increases. There is no practical limit on the width of the openings OP except that the openings should not be so wide as to compromise the structural integrity of the conductors with regard to, for example, gravity-induced deformation or sag, and the tensile strength of the transmission structure 1500. Alternatively, the width of the opening can be shorter than the widest possible width.

The method of forming the dielectric structure 1500 begins by laminating together the first dielectric support 1510, the first conductive shield 1520, and the conductive layer 1530 such that the first dielectric support 1510 is sandwiched between the first conductive shield 1520 and the conductive layer 1530. The first conductive shield 1520 can be implemented with, for example, a sheet of copper foil, but is not so limited. A conductor mask 1540 is then formed and patterned on the conductive layer 1530 (FIG. 15B), and the conductive layer 1530 is etched to form a series of conductors CC1-CCr, collectively referred to herein as CC, on the first dielectric support 1510 (FIG. 15C).

For larger cabling applications, there is no need to mask and etch a layer of conductive material to form the conductors CC. In this case, metal wires are sandwiched between the first and second dielectric supports 1510 and 1550 using lamination or other conventional processes for forming a multi-layer structure. The metal wires can be, for example, flat or round, but are not so limited.

Upon completion of the etching process, the conductor mask 1540 is removed from the conductive layer 1530. Following removal of the conductor mask 1540, a second dielectric support 1550 and a second conductive shield 1560 are laminated together (FIG. 15D) in a second lamination procedure. The structure including the second dielectric support 1550 and the second conductive shield 1560 is then laminated to conductors CC1-CCr. The second dielectric support 1550 and second conductive shield 1560 are prepared in a manner described above with reference to the first dielectric support 1510 and the first conductive shield 1520.

FIG. 15E is a side view of the basic transmission structure 1500 following the first and second lamination procedures, under an embodiment. Following the lamination procedures, the basic transmission structure 1500 includes conductors CC separated from the first and second conductive shields 1520 and 1560 by the thickness of the first and second dielectric supports 1510 and 1550, respectively. The air pressure in the openings OP is not limited to a particular pressure or range of pressures provided the pressure in the openings OP does not result in significant distortion of the transmission structure 1500 and does not significantly alter the electronic performance of the transmission structure 1500.

Following formation of the basic transmission structure 1500, electrical access to the conductors CC is formed, as shown in FIGS. 15F-15I. FIG. 15F shows the formation of openings 1570 that provide access to the conductors CC of the transmission structure 1500, under an embodiment. The openings 1570 of an embodiment are formed through the first and second shields 1520 and 1560, the first and second dielectric supports 1510 and 1550, and the conductors CC. Alternatively, the openings 1570 are formed through the first and second shields 1520 and 1560, and the first and second dielectric supports 1510 and 1550, so as to extend down to and expose the conductors CC, but not to penetrate the conductors CC. The openings 1570 can be formed in any of a number of conventional ways including, but not limited to, masking and etching, micro-machining, and drilling.

FIG. 15G shows the formation of conductive plugs 1574 through the openings 1570 of the transmission structure 1500, under an embodiment. At least one layer of masking material is formed and patterned on the first and second shields 1520 and 1560 to form a mask layer 1572 that exposes the openings 1570. The openings 1570 are then plated or filled using conventional techniques to form conductive plugs 1574 (e.g., plated through holes). Following formation of the conductive plugs 1574, mask layer 1572 is removed.

FIG. 15H shows a method for electrically isolating the conductive plugs 1574 of the transmission structure 1500, under an embodiment. This method begins with the formation and patterning of a layer of masking material on the first and second shields 1520 and 1560 to form a mask layer 1576. The mask layer 1576 protects the conductive plugs 1574, and exposes regions 1580 of the first and second shields 1520 around the conductive plugs 1574.

The exposed regions 1580 are then removed to form a gap 1578 between the conductive plugs 1574 and material of the first and second shields 1520 and 1560, with reference to FIG. 15I. The gaps 1578 serve to electrically isolate the conductive plugs 1574 from the first and second shields 1520 and 1560. Following formation of the gaps 1578, the mask layer 1576 is removed.

Alternative methods of forming an air dielectric transmission structure include forming interconnection structures on a printed circuit module for use in coupling high-speed signals among devices of the module, where the interconnection structure is an air dielectric transmission interconnection structure. As an example, a memory module of an embodiment uses an air dielectric transmission structure to interconnect signals among the memory devices and other electronic components of the memory module. The air dielectric transmission interconnection structure of an embodiment is formed on surface layers of module interconnection substrates, but is not so limited.

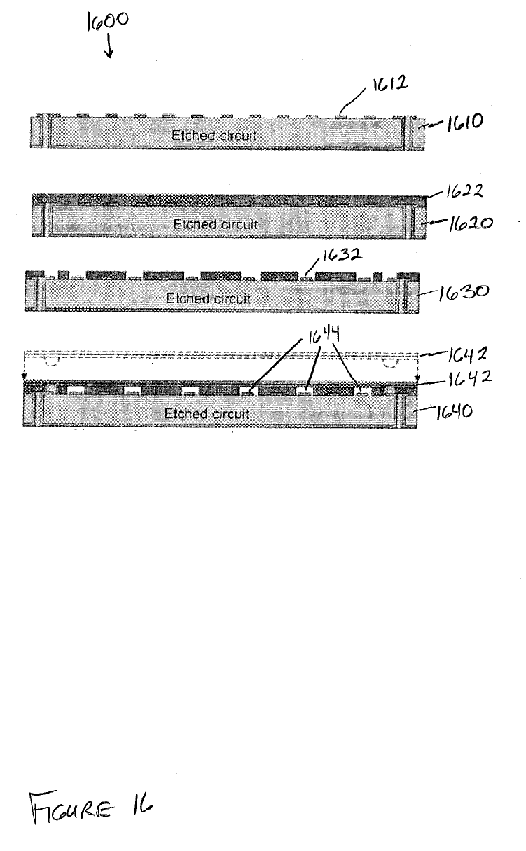

FIG. 16 shows a method 1600 for forming a printed circuit module 1640 that includes an air dielectric transmission structure 1644 on the surface layers of the module interconnection substrates, under an embodiment. The process begins with an etched circuit board structure 1610 that includes fully exposed circuit traces 1612. A coated circuit 1620 is formed by applying a soldermask 1622 to the etched circuit board structure 1610, for example by coating the soldermask 1620 as a wet film, or by dry film lamination. The soldermask 1622 is applied to cover all of the exposed circuit traces 1612, but is not so limited. Alternatively, the soldermask 1622 can be directly patterned using screen printing techniques, and/or any other applicable techniques known in the art.

Following its application, the soldermask 1622 is exposed with a desired pattern and developed using any of a number of techniques known in the art and appropriate to the etched circuit board structure 1610. Development of the soldermask 1622 results in the formation of an etched circuit structure 1630 in which those circuit traces selected for use in transmitting high-speed signals remain as exposed circuit traces 1632 while all other circuit traces remain encased in and insulated by material of the soldermask 1622.

A metal shield, foil, or metal-clad laminate 1642 is next attached to the etched circuit structure 1630 to form the printed circuit module 1640. The metal shield makes contact with the remaining material of the soldermask 1622 that encases the non-exposed circuit traces, but is not so limited. As such, the metal shield 1642 closes the gap over the exposed circuit traces 1632 resulting in the formation of the air dielectric transmission structures 1644 on the surface of the printed circuit module 1640. The air dielectric transmission structures 1644 include a series of isolated air cavities formed around the high-speed signaling circuit traces 1632, thereby providing an air dielectric in contact with the high-speed signaling circuit traces 1632. The metal foil 1642 serves as a reference ground for a microstrip or stripline circuit, for example, but is not so limited.

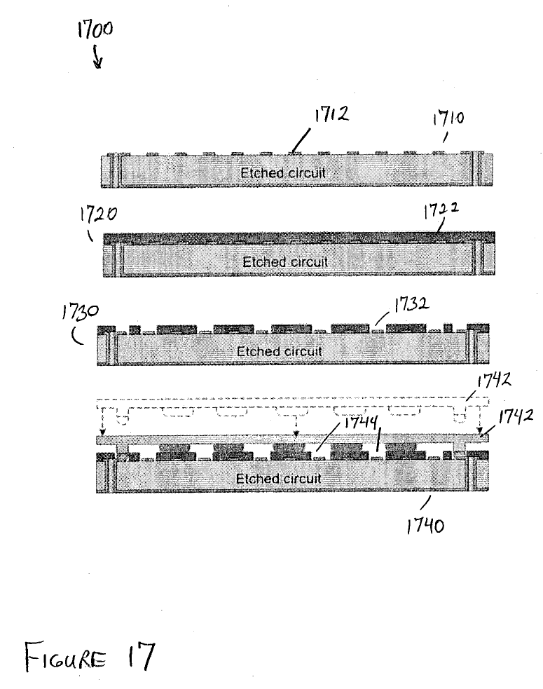

FIG. 17 shows a method 1700 for forming a printed circuit module 1740 that includes an air dielectric transmission structure 1744 on the surface layers of the module interconnection substrates, under an alternative embodiment. The process begins with an etched circuit board structure 1710 that includes fully exposed circuit traces 1712. A coated circuit 1720 is formed by applying a soldermask 1722 to the etched circuit board structure 1710. The soldermask 1722 is then developed to form an etched circuit structure 1730 that has exposed circuit traces 1732. The exposed circuit traces 1732 are those circuit traces identified for use in transmitting high-speed signals.

A metal cap 1742 is next attached to the etched circuit structure 1730 to form the printed circuit module 1740. The metal cap 1742 closes the gap over the exposed circuit traces 1732 resulting in the formation of the air dielectric transmission structures 1744 on the surface of the printed circuit module 1740. The metal cap 1742 is formed using processes known in the art, for example, embossing, stamping, molding, forming, and/or chemical milling, but is not so limited. Further, the metal cap 1742, which covers the exposed circuit traces 1732 at a predetermined distance from the traces 1732, can include pins that align the metal cap 1742. The metal cap 1742 can serve as a reference ground, but is not so limited.

FIG. 18 shows a method 1800 for forming a printed circuit module 1840 that includes an air dielectric transmission structure 1844 on the surface layers of the module interconnection substrates, under another alternative embodiment. The process begins with an etched circuit board structure 1810 that includes fully exposed circuit traces 1812. A metal cap 1842 is also formed that includes a pattern of insulating material 1846. The placement of the insulating material 1846 corresponds to the ones of the exposed circuit traces 1812 not designated for high-speed signal transmission.

The metal cap 1842 is subsequently attached to the etched circuit structure 1810 to form the printed circuit module 1840. Following attachment, the pattern of insulating material 1846 covers and insulates the ones of the exposed circuit traces 1812 not designated for high-speed signal transmission. The combination of the metal cap 1842 and the insulating material 1846 forms air gaps over ones of the exposed circuit traces 1812 designated for high-speed signal transmission. The air gaps form the air dielectric transmission structures 1844 on the surface of the printed circuit module 1840.

The metal cap 1842 of an embodiment also includes conductive joining material 1848 that electrically couples the metal cap 1842 to a ground structure of the printed circuit module 1840. This coupling between the metal cap 1842 and the ground structure of the printed circuit module 1840 allows the metal cap 1842 to function as a reference ground, but is not so limited.

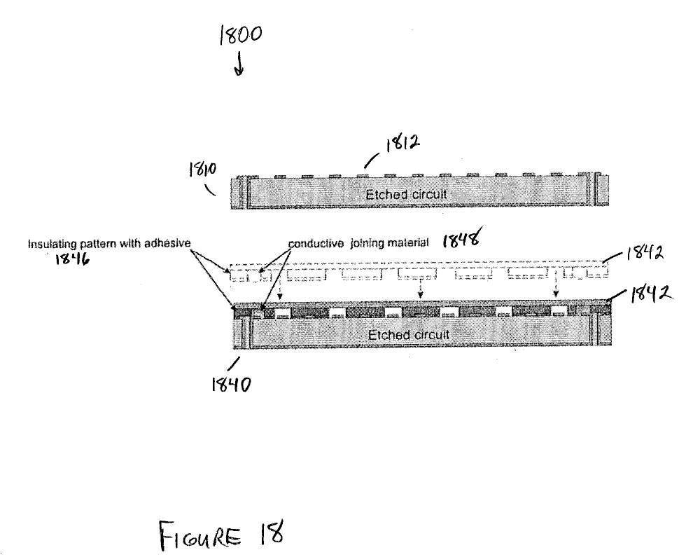

FIG. 19 is a memory module or card 1940 that includes an air dielectric transmission structure 1944 on the surface layers of the module interconnection substrates 1910, under any of the embodiments of FIGS. 16, 17 and 18. The memory module 1940, or printed circuit module, includes numerous electronic devices or components 1920, for example memory modules, interconnected by a signal transmission system 1930. The signal transmission system 1930 includes an air dielectric transmission structure 1944, as described above. The air dielectric transmission structure 1944 is integral with a copper ground shield or cap, as described above, but is not so limited.

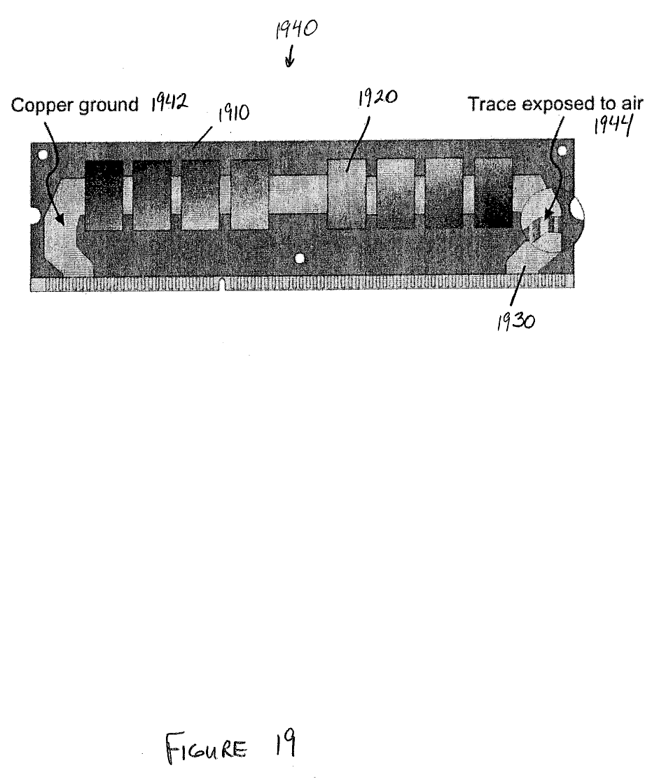

FIG. 20 is a side view of a memory module structure 2040 that includes an air dielectric transmission structure 2044 and a thermal spreader 2050, under any of the embodiments of FIGS. 16, 17 and 18. The memory module 2040 includes numerous electronic components 2020 mounted on the surface layers of the module interconnection substrate 2010. The electronic modules 2020 are interconnected via a signal transmission system that includes an air dielectric transmission structure 2044, as described above. Components of the signal transmission system, like the air dielectric transmission structure 2044, are integral with a ground shield or cap 2042, as described above. The ground shield 2042 overlays some number of the electronic components 2020, and is isolated from the electronic components 2020 using thermal grease 2060. Alternative embodiments can use alternative structures and/or compounds to isolate the electronic components 2020 from the ground shield 2042. The ground shield 2042, when isolated from physical contact with the electronic components 2020, is used as a thermal spreader, but is not so limited.

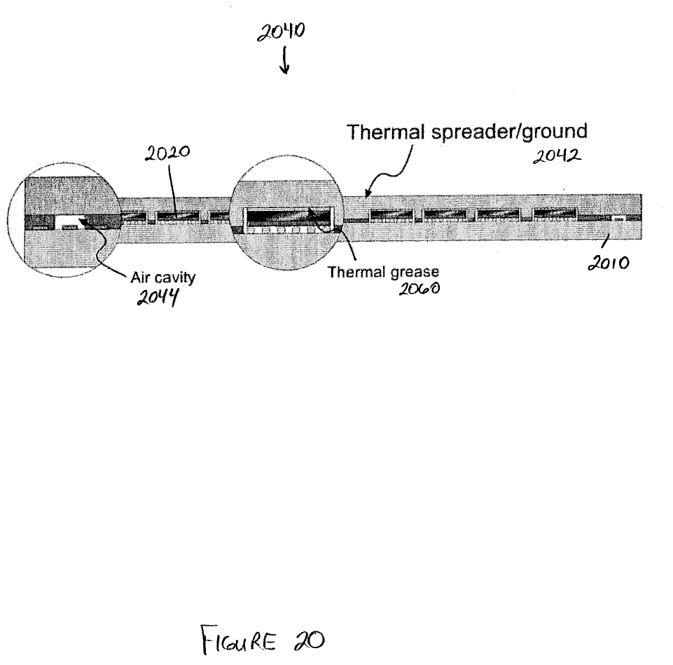

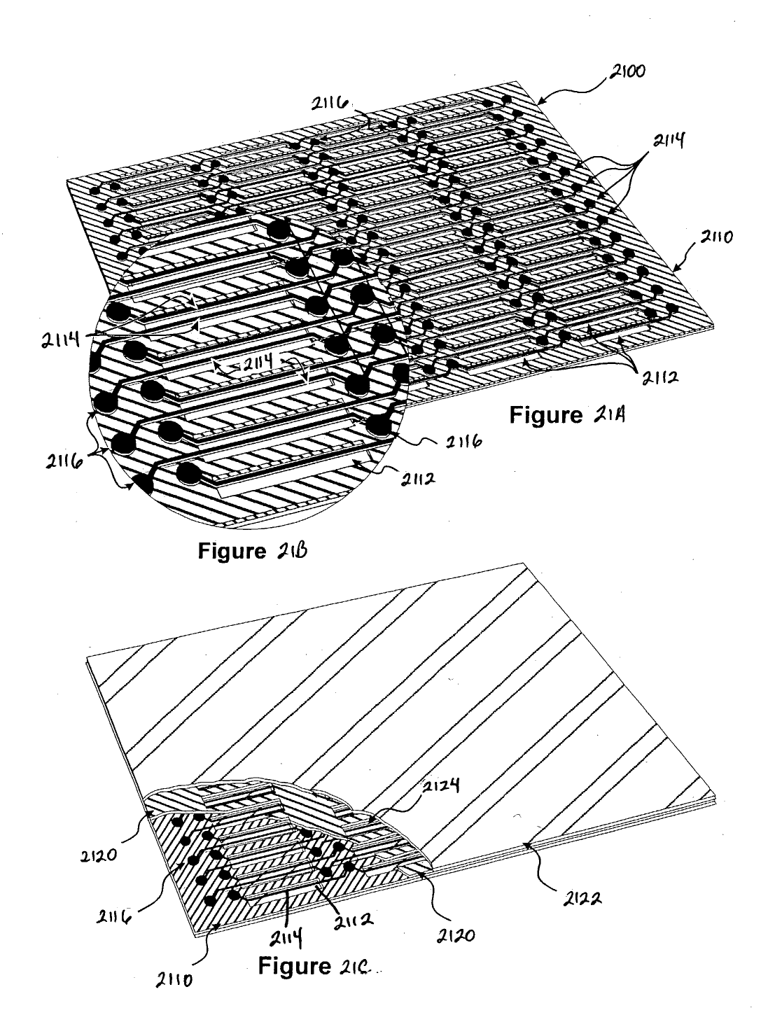

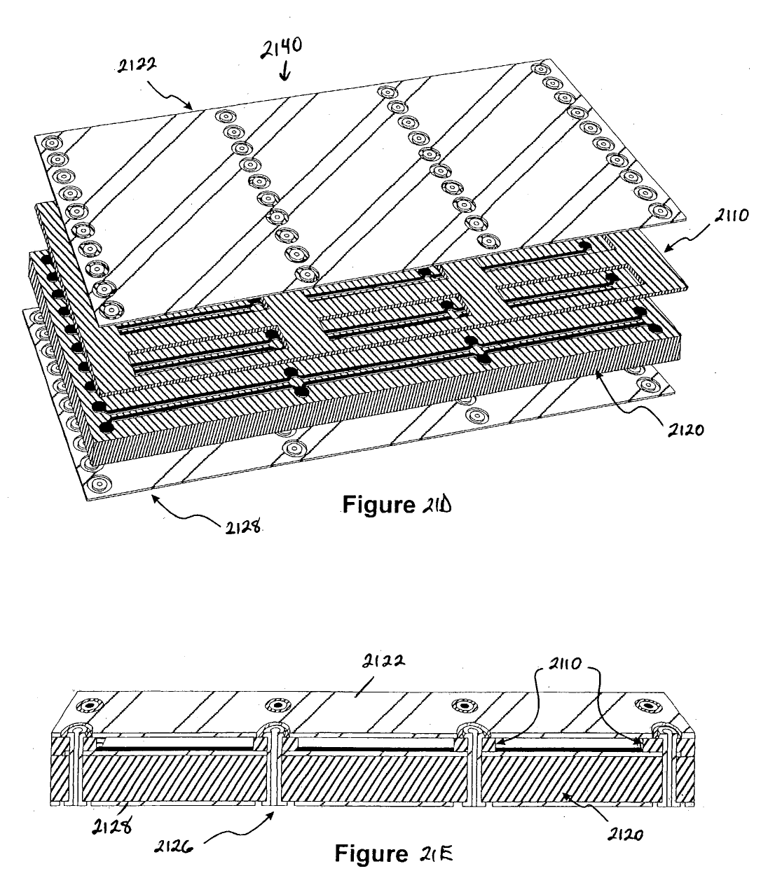

The transmission structures described above are used, for example, to form high-speed backplanes in signal transmission and processing systems. FIGS. 21A-21C show various views of a backplane 2100 including an air dielectric transmission structure, under an embodiment.

The backplane 2100 of an embodiment includes a dielectric support 2110 that has a number of openings 2112 which are arranged in rows and columns. In addition, backplane 2100 also includes a number of conductors 2114 that are formed on the dielectric support 2110 such that each conductor 2114 is formed over each opening 2112 in a row of openings. For example, two conductors 2114 are formed over each opening 2112 in a row of openings (except for the first and last rows of openings 2112 along the edge), but alternative embodiments can form any number of conductors 2114 over an opening. Furthermore, each conductor 2114 includes a number of contact regions 2116, where a contact region 2116 is formed at each end of each opening 2112, but the embodiment is not so limited.

The width of the openings 2112 is a function of the size of contact regions 2116. Further, there is no practical limit on the length of the openings 2112 except that the openings should not be so long as to compromise the structural integrity of the conductors with regard to, for example, gravity-induced deformation or sag, and the tensile strength of the transmission structure 2100. Alternatively, the length of the openings 2112 can be shorter than the longest possible limit.

The backplane 2100 also includes a layer of insulating material 2120 that is formed on the conductors 2114, and a first metal shield 2122 that is formed on the insulating material 2120. The insulating material 2120 of an embodiment has openings 2124 sized so that the insulating material 2120 only occasionally contacts conductors 2114. Alternatively, the openings 2124 are sized so that the conductors 2114 do not make contact with the insulating material 2120. The backplane 2100 can be used alone and in combination with one or more other layers of a backplane that includes multiple layers, where the other layers are of a similar or different construction. The backplane 2100 can also be used in or integrated with cards or modules that mate with a backplane, some of which are often referred to as daughter cards.

FIGS. 21D and 21E show views of a backplane 2140 including an air dielectric transmission structure with solid insulating material, under an alternative embodiment. The backplane 2140 has insulating material 2120 that is formed as a solid element with no openings, other than openings that accept the conductive plugs 2126. The conductive plugs 2126 are similar to the conductive plugs CP described above, but are not so limited. The backplane 2140 also includes a second metal shield 2128 that contacts dielectric support 2110. The backplane 2140 can be used alone, in combination with one or more other backplanes, and/or can be incorporated into a larger backplane.

FIG. 22 is a curved air dielectric transmission structure 2200, under an embodiment. The curved air dielectric transmission structure 2200, also referred to as a curved transmission structure 2200, includes a curved dielectric support 2210 with a number of openings 2212 formed through the curved dielectric support 2210. The curved dielectric support 2210 also includes a number of conductors 2214 and 2216 that are in contact with the dielectric support 2210. While two conductors 2214 and 2216 are shown in this example, alternative embodiments can have any number of conductors.

The spacing between the openings is adjusted in order to control the phase between signals transmitted over the conductors 2214 of the outside edge 2222, also referred to as outside conductors 2214, and the conductors 2216 of the inside edge 2226, also referred to as inside conductors 2216. The adjustment in the spacing between the openings of the outside edges 2222 and the openings of the inside edges 2226 introduces, for example, a delay in signal propagation along the conductor that corresponds to the path with the larger spacing among the openings.

For example, the curved transmission structure 2200 of an embodiment uses spacing that is relatively smaller between the openings 2212 on the outside edge 2222 of the curve when compared to the relatively larger spacing between the openings 2212 on the inside edge 2226 of the curve. Increasing the spacing between the openings 2212 of the inside edge 2226 introduces a slight delay in the propagation time of signals along the inside conductors 2216. The propagation delay of signals of the inside conductors 2216 (which traverse a shorter path) causes these signals to remain in phase with the signals of the outside conductors 2214 (which traverse a longer path).

FIG. 23 is a printed circuit board 2300 that includes an air dielectric transmission structure 2312, under an embodiment. The printed circuit board 2300 includes a number of devices 2310 that are formed on the circuit board 2300 along with an air dielectric transmission system 2312. In an alternative embodiment, the air dielectric transmission system 2312 is formed away from the circuit board 2300 and subsequently mounted on the circuit board 2300 as a component. Thus, the air dielectric transmission structures and systems described herein are used to route high speed signals from between different components or points on a circuit board as well as from a component/point on a circuit board to components/points on other circuit boards in the same or different electronic systems.

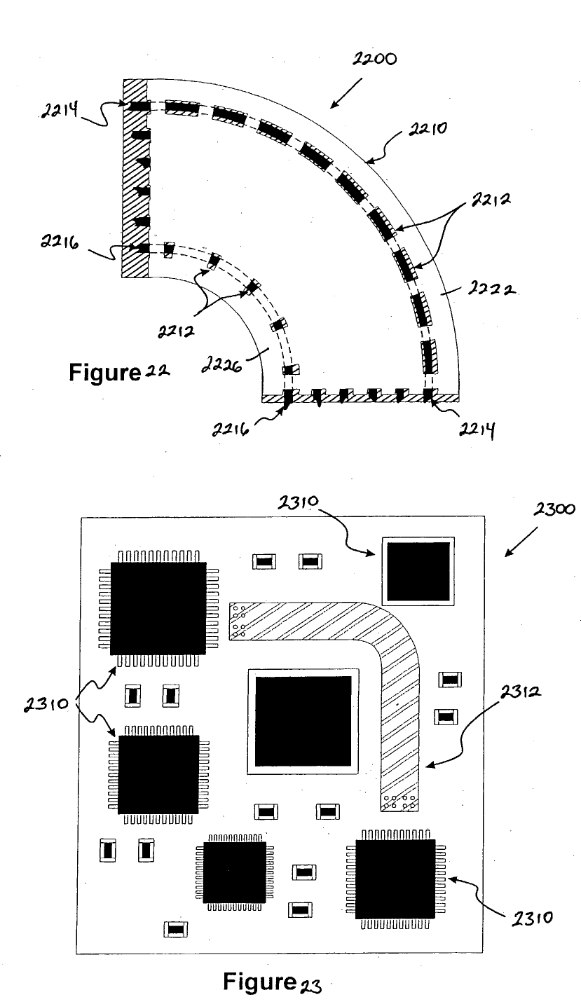

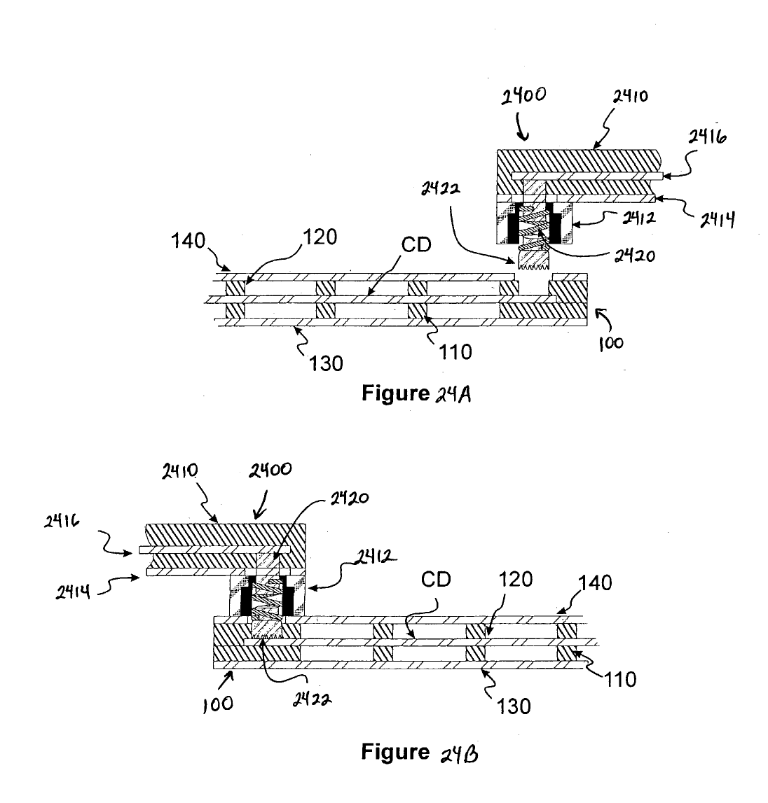

FIGS. 24A and 24B show a connector 2400 coupling to an air dielectric transmission structure 100, under an embodiment. The connector 2400 can be used with any of the air dielectric transmission structures described herein as well as alternative embodiments of the transmission structure anticipated under the descriptions herein. The connector 2400 includes a base member 2410 and at least one conductive ring 2412. The connector 2400 further includes a biasing member 2420, for example a spring, and a conductive plug 2422 that fits within the conductive ring 2412. The conductive plug 2422 is biased away from the base member 2410 by biasing member 2420, but is not so limited.

The base member 2410 also includes a first conductive path 2414 and a second conductive path 2416, but is not so limited. The first conductive path 2414 couples to the conductive ring 2412, and the second conductive path 2416 couples to the conductive plug 2422. When the connector 2400 is coupled to the transmission structure 100, the conductive ring 2412 forms an electrical coupling between the shield 140 and the first conductive path 2414 of the connector 2400. As described above, the shield 140 can be a ground reference or plane, but is not so limited. Also, when the connector 2400 and the transmission structure 100 are coupled, the biasing member 2420 insures contact between the conductive plug 2422 and components of the transmission structure 100, for example the conductors CD of the transmission structure 100.

The transmission systems described above include a system for concurrent transmission of multiple electrical signals comprising at least one signal conducting structure, the signal conducting structure including: at least one dielectric support; a first shield coupled to the dielectric support to form a first cavity between a first side of the dielectric support and the first shield; a second shield coupled to the dielectric support to form a second cavity between a second side of the dielectric support and the second shield; and at least one set of discrete conductors that contact the dielectric support such that each conductor is disposed across the dielectric support.

The dielectric support of an embodiment comprises at least one dielectric material in at least one of a solid form and a porous form.

The dielectric support of an embodiment includes a number of spaced-apart openings.

The dielectric support of an embodiment includes first and second sets of spaced-apart openings, wherein the first and second sets of spaced-apart openings are in at least one of an aligned configuration and an offset configuration.

The dielectric support of an embodiment includes at least one support member.

The conductors of the set of discrete conductors of an embodiment are narrower at regions of the conductor that contact the dielectric support.

The first shield and the second shield of an embodiment functions as a reference ground.

At least one of the first shield and the second shield of an embodiment further comprise an insulating core having first and second sides, wherein at least one of the first and second sides of the insulating core is clad with a conducting material.

The set of discrete conductors of an embodiment includes one or more conductors arranged in parallel.

The first cavity of an embodiment is filled with air, the second cavity is filled with dielectric material of the dielectric support, and the discrete conductors contact the first side of the dielectric support such that at least one side of the discrete conductors contact the air of the first cavity.

The first cavity of an embodiment is filled with air, the second cavity is filled with air, and the discrete conductors contact the first side of the dielectric support such that at least one side of the discrete conductors contact the air of the first cavity.

The set of discrete conductors of an embodiment includes a first set of conductors disposed across and contacting the first side of the dielectric support and a second set of conductors disposed across and contacting a second side of the dielectric support, wherein the first cavity is filled with air such that at least one side of the conductors of the first set of conductors contact the air of the first cavity, wherein the second cavity is filled with air such that at least one side of the conductors of the second set of conductors contact the air of the second cavity.

The dielectric support of an embodiment comprises one or more discrete support members oriented orthogonally to the discrete conductors.

The discrete conductors of an embodiment are integral to the dielectric support, wherein a first set of opposing sides of the discrete conductors contact the dielectric support and a second set of opposing sides of the discrete conductors contact the first and second cavities, wherein the first and second cavities are filled with air.

The system of an embodiment further comprises an insulating material that covers exposed surfaces of the discrete conductors, wherein the covering is at least one of a continuous covering and a discontinuous covering.

The system of an embodiment comprises a dielectric support that includes at least one material that fills the first and second cavities. The at least one material of an embodiment includes a first material that fills the first cavity and a second material that fills the second cavity. The at least one material of an embodiment is a particulate insulating material. The at least one material of an embodiment includes at least one piece of insulating material having at least one of a triangular shape, a pyramidal shape, and a wedge shape in at least one region of the material, wherein at least one point of the material contacts the discrete conductors. The at least one material of an embodiment includes at least one piece of insulating material having a cylindrical shape, wherein at least one point of the material contacts the discrete conductors.

The system of an embodiment further comprises a connector device for use in making electrical contact with the discrete conductors through the first and second shields, wherein the connector device is electrically coupled to the discrete conductors and electrically isolated from at least one of the first and second shields.

The transmission systems and structures described above include a structure for concurrently conducting a plurality of electrical signals, comprising: at least one dielectric support; a first shield coupled to the dielectric support to form a first cavity between a first side of the dielectric support and the first shield; a second shield coupled to the dielectric support to form a second cavity between a second side of the dielectric support and the second shield; and at least one set of discrete conductors that contact the dielectric support such that each conductor is disposed across the dielectric support.

The dielectric support of an embodiment comprises at least one dielectric material in at least one of a solid form and a porous form.

The dielectric support of an embodiment includes a number of spaced-apart openings.

The dielectric support of an embodiment includes at least one dielectric support member.

The set of discrete conductors of an embodiment includes one or more conductors arranged in parallel.

The first cavity of an embodiment is filled with air, the second cavity is filled with dielectric material of the dielectric support, and the discrete conductors contact the first side of the dielectric support such that at least one side of the discrete conductors contact the air of the first cavity.

The first cavity of an embodiment is filled with air, the second cavity is filled with air, and the discrete conductors contact the first side of the dielectric support such that at least one side of the discrete conductors contact the air of the first cavity.

The at least one set of discrete conductors of an embodiment includes a first set of conductors disposed across and contacting the first side of the dielectric support and a second set of conductors disposed across and contacting a second side of the dielectric support, wherein the first cavity is filled with air such that at least one side of the conductors of the first set of conductors contact the air of the first cavity, wherein the second cavity is filled with air such that at least one side of the conductors of the second set of conductors contact the air of the second cavity.

The dielectric support of an embodiment comprises one or more discrete support members oriented orthogonally to the discrete conductors.

The discrete conductors of an embodiment are integral to the dielectric support, wherein a first set of opposing sides of the discrete conductors contact the dielectric support and a second set of opposing sides of the discrete conductors contact the first and second cavities, wherein the first and second cavities are filled with air.

The structure of an embodiment includes a dielectric support that comprises at least one material that fills the first and second cavities. The material of an embodiment includes a first material that fills the first cavity and a second material that fills the second cavity. The material of an embodiment is a particulate insulating material. The material of an embodiment includes at least one piece of insulating material having at least one of a triangular shape, a pyramidal shape, and a wedge shape in at least one region of the material, wherein at least one point of the material contacts the discrete conductors. The material of an embodiment includes at least one piece of insulating material having a cylindrical shape, wherein at least one point of the material contacts the discrete conductors.

The transmission systems and structures described above include a method of forming a transmission structure, the method comprising: dividing a plurality of exposed conductors into first and second sets of conductors, wherein the plurality of exposed conductors are discrete conductors formed on a dielectric support; forming a pattern of dielectric material including dielectric material placed so as to coincide with a location of exposed surfaces of each conductor of the first set; coupling a first side of the pattern to a first side of a shield; and coupling a second side of the pattern to the dielectric support, wherein the dielectric material of the pattern encases exposed surfaces of each conductor of the first set, wherein conductors of the second set remain exposed and the pattern of dielectric material and the shield form air cavities around conductors of the second set.

The transmission systems and structures described above include another method of forming a transmission structure, the method comprising: dividing a plurality of exposed conductors into first and second sets of conductors, wherein the plurality of exposed conductors are discrete conductors formed on a dielectric support; forming a volume of dielectric material around exposed surfaces of each conductor of the first set, wherein conductors of the second set remain exposed; and coupling a first side of a shield to the volumes of dielectric material so that the first side of the shield faces the exposed conductors of the second set, wherein the shield and the volumes of dielectric material form air cavities around conductors of the second set.

The formation of a volume of dielectric material of an embodiment further comprises: applying at least one layer of the dielectric material over the dielectric support and the plurality of exposed conductors; and selectively removing portions of the dielectric material from around conductors of the second set.

The dielectric material of an embodiment is a soldermask.

The shield of an embodiment is at least one of a conductive shield, a conductive foil, a metal cap, and a metal-clad laminate.

The shield of an embodiment is a reference ground.

In an embodiment, the method further comprises forming the dielectric support by: laminating the dielectric support to a ground shield and a layer of conductive material; and selectively removing the layer of conductive material to form a plurality of exposed discrete conductors on the dielectric support. The shield of an embodiment can be electrically coupled to the ground support.

The transmission systems and structures described above include yet another method of forming a transmission structure, the method comprising: positioning a plurality of discrete conductors between a first and second shield using at least one dielectric support, wherein a first cavity is formed between the conductors and the first shield and a second cavity is formed between the conductors and the second shield; and loading the first cavity with a first dielectric material and the second cavity with a second dielectric material, wherein exposed surfaces of the conductors are in contact with at least one of the first and second dielectric materials.

The transmission systems and structures described above include a signal transmission structure, comprising: a plurality of spaced-apart dielectric elements; a first shield coupled to a first set of discrete conductors and a first side of the dielectric elements; and a second shield coupled to a second set of discrete conductors and a second side of the dielectric elements, wherein air gaps are formed between corresponding conductors of the first and second set of discrete conductors.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import, when used in this application, shall refer to this application as a whole and not to any particular portions of this application. When the word “or” is used in reference to a list of two or more items, that word covers all of the following interpretations of the word: any of the items in the list, all of the items in the list and any combination of the items in the list.

The above description of illustrated embodiments of the invention is not intended to be exhaustive or to limit the invention to the precise form disclosed. While specific embodiments of, and examples for, the invention are described herein for illustrative purposes, various equivalent modifications are possible within the scope of the invention, as those skilled in the relevant art will recognize. The teachings of the invention provided herein can be applied to other transmission structures, not only for the transmission structures described above.

The elements and acts of the various embodiments described above can be combined by one skilled in the art using the descriptions herein to provide further embodiments. These and other changes can be made to the invention in light of the above detailed description.

All of the above references and United States patent applications are incorporated herein by reference. Aspects of the invention can be modified, if necessary, to employ the systems, functions and concepts of the various patents and applications described above to provide yet further embodiments of the invention.

In general, in the following claims, the terms used should not be construed to limit the invention to the specific embodiments disclosed in the specification and the claims, but should be construed to include all structures and systems that operate under the claims. Accordingly, the invention is not limited by the disclosure, but instead the scope of the invention is to be determined entirely by the claims.

While certain aspects of the invention are presented below in certain claim forms, the inventor contemplates the various aspects of the invention in any number of claim forms. Accordingly, the inventors reserve the right to add additional claims after filing the application to pursue such additional claim forms for other aspects of the invention.

What we claim is:

1. A system for concurrent transmission of multiple electrical signals comprising at least one signal conducting structure, the signal conducting structure including:
at least one dielectric support;
a first shield coupled to the dielectric support to form a first cavity between a first side of the dielectric support and the first shield;
a second shield coupled to the dielectric support to form a second cavity between a second side of the dielectric support and the second shield; and
at least one set of discrete conductors that contact the dielectric support such that each conductor is disposed across the dielectric support.

2. The system of claim 1, wherein the dielectric support comprises at least one dielectric material in at least one of a solid form and a porous form.

3. The system of claim 1, wherein the dielectric support includes a number of spaced-apart openings.

4. The system of claim 1, wherein the dielectric support includes first and second sets of spaced-apart openings, wherein the first and second sets of spaced-apart openings are in at least one of an aligned configuration and an offset configuration.

5. The system of claim 1, wherein the dielectric support includes at least one support member.

6. The system of claim 1, wherein at least one conductor of the set of discrete conductors is narrower at regions of the conductor that contact the dielectric support.

7. The system of claim 1, wherein at least one of the first shield and the second shield serves as a reference ground.

8. The system of claim 1, wherein at least one of the first shield and the second shield further comprises an insulating core having first and second sides, wherein at least one of the first and second sides of the insulating core is clad with a conducting material.

9. The system of claim 1, wherein the set of discrete conductors includes one or more conductors arranged in parallel.

10. The system of claim 1, wherein the first cavity is filled with air, the second cavity is filled with dielectric material of the dielectric support, and the discrete conductors contact the first side of the dielectric support such that at least one side of the discrete conductors contact the air of the first cavity.

11. The system of claim 1, wherein the first cavity is filled with air, the second cavity is filled with air, and the discrete conductors contact the first side of the dielectric support such that at least one side of the discrete conductors contact the air of the first cavity.

12. The system of claim 1, wherein the at least one set of discrete conductors includes a first set of conductors disposed across and contacting the first side of the dielectric support and a second set of conductors disposed across and contacting a second side of the dielectric support, wherein the first cavity is filled with air such that at least one side of the conductors of the first set of conductors contact the air of the first cavity, wherein the second cavity is filled with air such that at least one side of the conductors of the second set of conductors contact the air of the second cavity.

13. The system of claim 1, wherein the dielectric support comprises one or more discrete support members oriented orthogonally to the discrete conductors.

14. The system of claim 1, wherein the discrete conductors are integral to the dielectric support, wherein a first set of opposing sides of the discrete conductors contact the dielectric support and a second set of opposing sides of the discrete conductors contact the first and second cavities, wherein the first and second cavities are filled with air.

15. The system of claim 1, further comprising an insulating material that covers exposed surfaces of the discrete conductors, wherein the covering is at least one of a continuous covering and a discontinuous covering.

16. The system of claim 1, wherein the dielectric support comprises at least one material that fills the first and second cavities.

17. The system of claim 16, wherein the at least one material includes a first material that fills the first cavity and a second material that fills the second cavity.

18. The system of claim 16, wherein the material is a particulate insulating material.

19. The system of claim 16, wherein the material includes at least one piece of insulating material having at least one of a triangular shape, a pyramidal shape, and a wedge shape in at least one region of the material, wherein at least one point of the material contacts the discrete conductors.

20. The system of claim 16, wherein the material includes at least one piece of insulating material having a cylindrical shape, wherein at least one point of the material contacts the discrete conductors.

21. The system of claim 1, further comprising a connector device for use in making electrical contact with the discrete conductors through the first and second shields, wherein the connector device is electrically coupled to the discrete conductors and electrically isolated from at least one of the first and second shields.

22. A structure for concurrently conducting a plurality of electrical signals, comprising:
at least one dielectric support;
a first shield coupled to the dielectric support to form a first cavity between a first side of the dielectric support and the first shield;
a second shield coupled to the dielectric support to form a second cavity between a second side of the dielectric support and the second shield; and
at least one set of discrete conductors that contact the dielectric support such that each conductor is disposed across the dielectric support.

23. The structure of claim 22, wherein the dielectric support comprises at least one dielectric material in at least one of a solid form and a porous form.

24. The structure of claim 22, wherein the dielectric support includes a number of spaced-apart openings.

25. The structure of claim 22, wherein the dielectric support includes at least one dielectric support member.

26. The structure of claim 22, wherein the set of discrete conductors includes one or more conductors arranged in parallel.

27. The structure of claim 22, wherein the first cavity is filled with air, the second cavity is filled with dielectric material of the dielectric support, and the discrete conductors contact the first side of the dielectric support such that at least one side of the discrete conductors contact the air of the first cavity.

28. The structure of claim 22, wherein the first cavity is filled with air, the second cavity is filled with air, and the discrete conductors contact the first side of the dielectric support such that at least one side of the discrete conductors contact the air of the first cavity.

29. The structure of claim 22, wherein the at least one set of discrete conductors includes a first set of conductors disposed across and contacting the first side of the dielectric support and a second set of conductors disposed across and contacting a second side of the dielectric support, wherein the first cavity is filled with air such that at least one side of the conductors of the first set of conductors contact the air of the first cavity, wherein the second cavity is filled with air such that at least one side of the conductors of the second set of conductors contact the air of the second cavity.

30. The structure of claim 22, wherein the dielectric support comprises one or more discrete support members oriented orthogonally to the discrete conductors.

31. The structure of claim 22, wherein the discrete conductors are integral to the dielectric support, wherein a first set of opposing sides of the discrete conductors contact the dielectric support and a second set of opposing sides of the discrete conductors contact the first and second cavities, wherein the first and second cavities are filled with air.

32. The structure of claim 22, wherein the dielectric support comprises at least one material that fills the first and second cavities.

33. The structure of claim 32, wherein the at least one material includes a first material that fills the first cavity and a second material that fills the second cavity.

34. The structure of claim 32, wherein the material is a particulate insulating material.

35. The structure of claim 32, wherein the material includes at least one piece of insulating material having at least one of a triangular shape, a pyramidal shape, and a wedge shape in at least one region of the material, wherein at least one point of the material contacts the discrete conductors.

36. The structure of claim 32, wherein the material includes at least one piece of insulating material having a cylindrical shape, wherein at least one point of the material contacts the discrete conductors.

37. A method of forming a transmission structure, the method comprising:
dividing a plurality of exposed conductors into first and second sets of conductors, wherein the plurality of exposed conductors are discrete conductors formed on a dielectric support;
forming a pattern of dielectric material including dielectric material placed so as to coincide with a location of exposed surfaces of each conductor of the first set;
coupling a first side of the pattern to a first side of a shield; and
coupling a second side of the pattern to the dielectric support, wherein the dielectric material of the pattern encases exposed surfaces of each conductor of the first set, wherein conductors of the second set remain exposed and the pattern of dielectric material and the shield form air cavities around conductors of the second set.

38. A method of forming a transmission structure, the method comprising:
dividing a plurality of exposed conductors into first and second sets of conductors, wherein the plurality of exposed conductors are discrete conductors formed on a dielectric support;
forming a volume of dielectric material around exposed surfaces of each conductor of the first set, wherein conductors of the second set remain exposed; and
coupling a first side of a shield to the volumes of dielectric material so that the first side of the shield faces the exposed conductors of the second set, wherein the shield and the volumes of dielectric material form air cavities around conductors of the second set.

39. The method of claim 38, wherein forming a volume of dielectric material further comprises:
applying at least one layer of the dielectric material over the dielectric support and the plurality of exposed conductors; and
selectively removing portions of the dielectric material from around conductors of the second set.

40. The method of claim 38, wherein the dielectric material is a soldermask.

41. The method of claim 38, wherein the shield is at least one of a conductive shield, a conductive foil, a metal cap, and a metal-clad laminate.

42. The method of claim 38, wherein the shield is a reference ground.

43. The method of claim 38, further comprising forming the dielectric support by:
laminating the dielectric support to a ground shield and a layer of conductive material; and
selectively removing the layer of conductive material to form a plurality of exposed discrete conductors on the dielectric support.

44. The method of claim 43, further comprising electrically coupling the shield to the ground support.

45. A method of forming a transmission structure, the method comprising:
positioning a plurality of discrete conductors between a first and second shield using at least one dielectric support, wherein a first cavity is formed between the conductors and the first shield and a second cavity is formed between the conductors and the second shield; and
loading the first cavity with a first dielectric material and the second cavity with a second dielectric material, wherein exposed surfaces of the conductors are in contact with at least one of the first and second dielectric materials.

46. A signal transmission structure, comprising:
a plurality of spaced-apart dielectric elements;
a first shield coupled to a first set of discrete conductors and a first side of the dielectric elements; and
a second shield coupled to a second set of discrete conductors and a second side of the dielectric elements, wherein air gaps are formed between corresponding conductors of the first and second set of discrete conductors.
